(19) United States
(12) Patent Application Publication
(10) Pub. No.: US 2010/0196832 A1
(43) Pub. Date: Aug. 5, 2010

(54) EXPOSURE APPARATUS, EXPOSING METHOD, LIQUID IMMERSION MEMBER AND DEVICE FABRICATING METHOD

(75) Inventor: Hiroyuki Nagasaka, Kumagaya-shi (JP)

Correspondence Address: OLIFF & BERRIDGE, PLC, P.O. BOX 320850, ALEXANDRIA, VA, 22320-4850, US

(73) Assignee: NIKON CORPORATION, Tokyo (JP)

(21) Appl. No.: 12/692,087

(22) Filed: Jan. 22, 2010

Related U.S. Application Data
(60) Provisional application No. 61/202,143, filed on Jan. 30, 2009.

(51) Int. Cl. G03F 7/20; G03B 27/52; G03B 27/32

(52) U.S. Cl. 430/325; 355/30; 355/77

(57) ABSTRACT

An exposure apparatus comprises: an optical system, which has an emergent surface wherefrom exposure light emerges; a first surface, which is disposed at least partly around an optical path of the exposure light from the emergent surface; and a second surface, which is disposed at least partly around the first surface; and a first supply port, which is disposed at least partly around the first surface such that it faces in an outward radial direction with respect to an optical axis of the projection optical system, that supplies a first liquid to the second surface; wherein, during at least part of an exposure of a substrate, a front surface of the substrate opposes the emergent surface, the first surface, and the second surface; and the substrate is exposed with the exposure light that emerges from the emergent surface and transits a second liquid between the emergent surface and the front surface of the substrate.

### CROSS-REFERENCE TO RELATED APPLICATION

This application is a non-provisional application claiming priority to and the benefit of U.S. provisional application No. 61/202,143, filed Jan. 30, 2009. The entire contents of which are incorporated herein by reference.

### BACKGROUND

1. Field of the Invention

The present invention relates to an exposure apparatus, an exposing method, a liquid immersion member, and a device fabricating method.

2. Description of Related Art

As disclosed in, for example, U.S. Patent Application Publication No. 2005/259234, among exposure apparatuses used in photolithography, an immersion exposure apparatus is known that exposes a substrate with exposure light that emerges from a projection optical system and transits a liquid.

In an immersion exposure apparatus, if an object (i.e., a substrate), whereon an immersion area is formed, is moved at high speed, then there is a possibility that the liquid will leak, the liquid (a film, a drop, or the like) will remain on the object, and the like. As a result, there is a possibility that, for example, exposure failures will occur or defective devices will be produced. Moreover, if the movement velocity of the object is lowered in order to satisfactorily hold the liquid, then there is a possibility that throughput will decline.

### SUMMARY

It is an object of some aspects of the present invention to provide an exposure apparatus, an exposing method and a liquid immersion member that can prevent liquid from remaining on an object. It is another object of some aspects of the present invention to provide a device fabricating method that can prevent defective devices from being produced while preventing throughput from declining.

A first aspect of the invention provides an exposure apparatus that comprises: an optical system, which has an emergent surface wherefrom exposure light emerges; a first surface, at least part of which is disposed around an optical path of the exposure light from the emergent surface; a second surface, at least part of which is disposed around the first surface; and a first supply port which is disposed at least partly around the first surface such that it faces in an outward radial direction with respect to an optical axis of the projection optical system and it supplies a first liquid to the second surface; wherein, during at least part of an exposure of the substrate, a front surface of the substrate opposes the emergent surface, the first surface, and the second surface; and the substrate is exposed with the exposure light that emerges from the emergent surface via a second liquid between the emergent surface and the front surface of the substrate.

A second aspect of the invention provides a device fabricating method that comprises the steps of: exposing a substrate using an exposure apparatus according to the first aspect; and developing the exposed substrate.

A third aspect of the invention provides an exposing method that comprises the steps of: causing a first surface, which is disposed at least partly around an optical path of exposure light that emerges from an emergent surface of an optical system, and a second surface, which is disposed at least partly around the first surface, to oppose a substrate; at least partly around the first surface, supplying a first liquid from a first supply port, which is disposed such that it faces in an outward radial direction with respect to the optical axis of the optical system, to the second surface; forming an immersion space with the second liquid between at least part of the emergent surface, the first surface, and the second surface and the front surface of the substrate by supplying a second liquid via a second supply port, which is different than the first supply port, such that the optical path of the exposure light between the emergent surface and the substrate is filled with the second liquid; and exposing the substrate with the exposure light that emerges from the emergent surface and passes through the second liquid between the emergent surface and the substrate.

A fourth aspect of the invention provides an exposing method that comprises the steps of: causing a first surface, which is disposed at least partly around an optical path of exposure light that emerges from an emergent surface of an optical system, and a second surface, which is disposed at least partly around the first surface, to oppose a substrate; at least partly around the first surface, forming a flow of a liquid in an outward radial direction with respect to the optical axis of the optical system by supplying a first liquid to the second surface; forming an immersion space with a second liquid between at least part of the emergent surface, the first surface, and the second surface and a front surface of the substrate such that the optical path of the exposure light between the emergent surface and the substrate is filled with the second liquid; and exposing the substrate with the exposure light that emerges from the emergent surface and transits the second liquid between the emergent surface and the substrate; wherein, a gas space is present between a surface of the liquid, which flows in the outward radial direction with respect to the optical axis of the optical system, and the front surface of the substrate.

A fifth aspect of the invention provides a device fabricating method that comprises the steps of: exposing a substrate using an exposing method according to the third or fourth aspects of the invention; and developing the exposed substrate.

A sixth aspect of the invention provides a liquid immersion member that is disposed in an exposure apparatus that exposes a substrate with an exposure light from an emergent surface of an optical system, the liquid immersion member comprising: a first surface, which is disposed at least partly around an optical path of the exposure light from the emergent surface; and a second surface, which is disposed at least partly around the first surface; a first supply port, which is disposed at least partly around the first surface such that the first supply port faces in an outward radial direction with respect to an optical axis of the optical system, and which supplies a first liquid to the second surface; and a second supply port that supplies a second liquid to an optical path of the exposure light.

According to some aspects of the present invention, it is possible to prevent exposure failures from occurring while preventing throughput from declining. In addition, according to some aspects of the present invention, it is possible to prevent defective devices from being produced while preventing throughput from declining.

### BRIEF DESCRIPTION OF THE DRAWINGS

FIG. 1 is a schematic block diagram that shows one example of an exposure apparatus according to a first embodiment.

FIG. 2 is a partial, enlarged view of the exposure apparatus according to the first embodiment.

FIG. 3 shows an immersion member according to the first embodiment, viewed from above.

FIG. 4 shows the immersion member according to the first embodiment, viewed from below.

FIG. 5 is a view that shows the vicinity of the liquid immersion member according to the first embodiment.

FIG. 6 is a schematic drawing that shows a liquid immersion member according to a comparative example.

FIG. 7 is a schematic drawing that shows the liquid immersion member according to the first embodiment.

FIG. 8 is a view that shows the vicinity of the liquid immersion member according to a second embodiment.

FIG. 9 is a view that shows the vicinity of the liquid immersion member according to the second embodiment.

FIG. 10 is a view that shows the vicinity of the liquid immersion member according to a third embodiment.

FIG. 11 is a view that shows the vicinity of the liquid immersion member according to the third embodiment.

FIG. 12 is a view that shows the vicinity of the liquid immersion member according to the third embodiment.

FIG. 13 is a view that shows the vicinity of the liquid immersion member according to the third embodiment.

FIG. 14 is a view that shows the vicinity of the liquid immersion member according to a fourth embodiment.

FIG. 15 is a side view that shows the liquid immersion member according to a fifth embodiment.

FIG. 16 shows the immersion member according to the fifth embodiment, viewed from below.

FIG. 17 is a flow chart for explaining one example of a process of fabricating a microdevice.

### DESCRIPTION OF EMBODIMENTS

The following text explains the embodiments of the present invention, referencing the drawings; however, the present invention is not limited thereto. The explanation below defines an XYZ orthogonal coordinate system and the positional relationships among members are explained referencing this system. Prescribed directions within the horizontal plane are the X axial directions, directions orthogonal to the X axial directions in the horizontal plane are the Y axial directions, and directions orthogonal to the X axial directions and the Y axial directions are the Z axial directions (i.e., the vertical directions). In addition, the rotational (i.e., inclinational) directions around the X, Y, and Z axes are the θX, θY, and θZ directions, respectively.

### First Embodiment

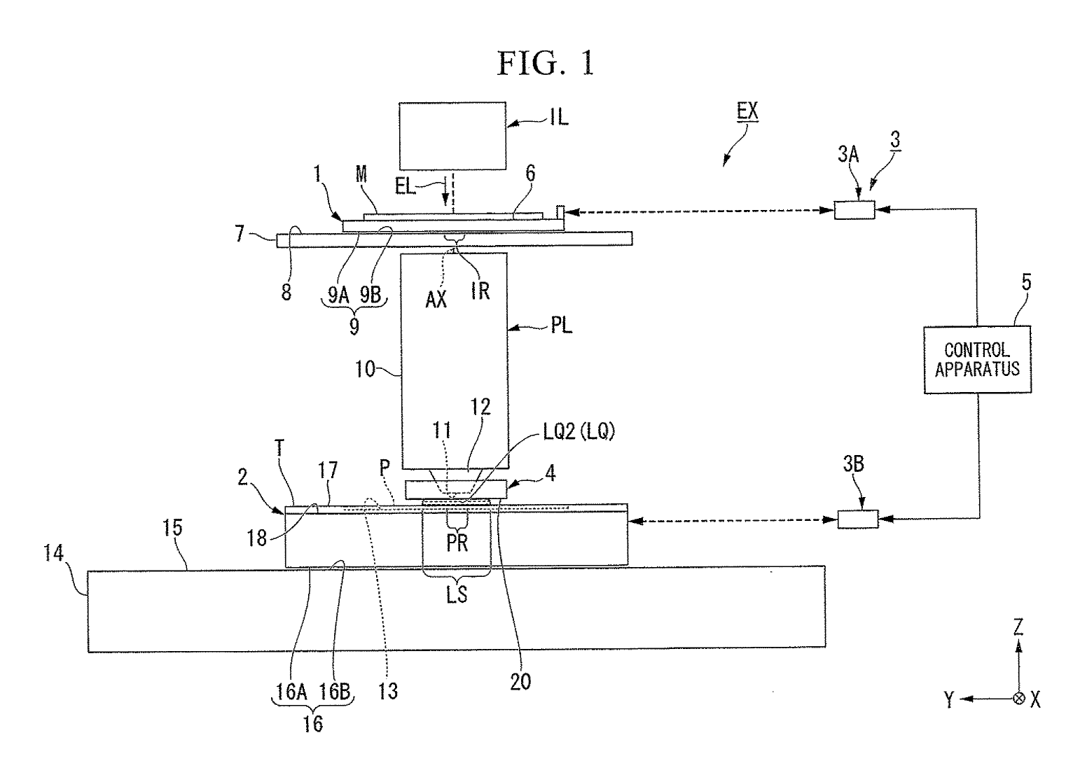

A first embodiment will now be explained. FIG. 1 is a schematic block drawing that shows one example of an exposure apparatus EX according to the first embodiment. The exposure apparatus EX of the present embodiment is an immersion exposure apparatus that exposes a substrate P with exposure light EL that transits a liquid. Furthermore, in the present embodiment as discussed below, a first liquid LQ1 and a second liquid LQ2 are used as the liquid and the exposure light EL is radiated to the substrate P through the second liquid LQ2.

In FIG. 1, the exposure apparatus EX comprises: a movable mask stage 1 that holds a mask M; a movable substrate stage 2 that holds the substrate P; an interferometer system 3 that optically measures the positions of the mask stage 1 and the substrate stage 2; an illumination system IL that illuminates the mask M with the exposure light EL; a projection optical system PL that projects an image of a pattern of the mask M, which is illuminated by the exposure light EL, to the substrate P; a liquid immersion member 4, which is capable of forming an immersion space LS such that at least part of the optical path of the exposure light EL is filled with the second liquid LQ2; and a control apparatus 5 that controls the operation of the entire exposure apparatus EX.

The mask M may be, for example, a reticle wherein a device pattern that is projected onto the substrate P is formed. The mask M may be, for example, a transmissive mask that comprises a transparent plate, such as a glass plate, and a pattern, which is formed on the transparent plate using a light shielding material such as chrome. Furthermore, the mask M may alternatively be a reflective mask.

The substrate P is a substrate for fabricating devices. The substrate P comprises a base material, such as a semiconductor wafer, and a multilayer film that is formed thereon. The multilayer film is a film wherein multiple films, which include at least a photosensitive film, are layered. The photosensitive film is formed from a photosensitive material. In addition, the multilayer film may include, for example, an antireflection film or a protective film (i.e., a topcoat film) that protects the photosensitive film.

The illumination system IL radiates the exposure light EL to a prescribed illumination area IR. The illumination area IR includes a position whereto the exposure light EL that emerges from the illumination system IL can be radiated. The illumination system IL illuminates at least part of the mask M, which is disposed in the illumination area IR, with the exposure light EL, which has a uniform luminous flux intensity distribution. Examples of light that can be used as the exposure light EL emitted from the illumination system IL include: deep ultraviolet (DUV) light such as a bright line (g-line, h-line, or i-line) light emitted from, for example, a mercury lamp, and KrF excimer laser light (with a wavelength of 248 nm); and vacuum ultraviolet (VUV) light such as ArF excimer laser light (with a wavelength of 193 nm) and F₂ laser light (with a wavelength of 157 nm). In the present embodiment, ArF excimer laser light, which is ultraviolet light (e.g., vacuum ultraviolet light), is used as the exposure light EL.

The mask stage 1 comprises a mask holding part 6, which releasably holds the mask M, and is capable of moving on a guide surface 8 of a first base plate 7 in the state wherein it holds the mask M. The mask stage 1 is capable of holding the mask M and moving with respect to the illumination area IR by the operation of a drive system 9. The drive system 9 comprises a planar motor that comprises a slider 9A, which is disposed on the mask stage 1, and a stator 9B, which is disposed on the first base plate 7. The planar motor, which is capable of moving the mask stage 1, is disclosed in, for example, U.S. Pat. No. 6,452,292. The mask stage 1 is capable of moving in six directions, i.e., the X, Y, and Z axial directions and the θX, θY, and θZ directions, by the operation of the drive system 9.

The projection optical system PL radiates the exposure light EL to a prescribed projection area PR. The projection optical system PL projects an image of the pattern of the mask M to at least part of the substrate P, which is disposed in the projection area PR, with a prescribed projection magnification. A holding member 10 (i.e., a lens barrel) holds the plurality of optical elements of the projection optical system PL. The projection optical system PL of the present embodiment is a reduction system that has a projection magnification of, for example, ¼, ⅕, or ⅛. Furthermore, the projection optical system PL may also be a unity magnification system or an enlargement system. In the present embodiment, an optical axis AX of the projection optical system PL is parallel to the Z axis. In addition, the projection optical system PL may be a dioptric system that does not include catoptric elements, a catoptric system that does not include dioptric elements, or a catadioptric system that includes both catoptric and dioptric elements. In addition, the projection optical system PL may form either an inverted or an erect image.

The projection optical system PL has an emergent surface 11 wherefrom the exposure light EL emerges and travels toward the image plane of the projection optical system PL. A last optical element 12, which is the optical element among the plurality of optical elements of the projection optical system PL that is closest to the image plane of the projection optical system PL, has an emergent surface 11. The projection area PR includes a position whereto the exposure light EL that emerges from the emergent surface 11 can be radiated. In the present embodiment, the emergent surface 11 faces the −Z direction (i.e., downward) and is parallel to the XY plane. Furthermore, the emergent surface 11, which faces the −Z direction, may be a convex surface or a concave surface.

In the present embodiment, the optical axis AX in the vicinity of the image plane of the projection optical system PL, namely, the optical axis AX of the last optical element 12, is substantially parallel to the Z axis. Furthermore, the optical axis defined by the optical element adjacent to the last optical element 12 may be regarded as the optical axis thereof. In addition, in the present embodiment, the image plane of the projection optical system PL is substantially parallel to the XY plane, which includes the X axis and the Y axis. In addition, in the present embodiment, the image plane is substantially horizontal. However, the image plane does not have to be parallel to the XY plane and may be a curved surface.

The substrate stage 2 comprises a substrate holding part 13, which releasably holds the substrate P and is capable of moving on a guide surface 15 of a second base plate 14. The substrate stage 2 holds the substrate P and is capable of moving with respect to the projection area PR by the operation of a drive system 16. The drive system 16 comprises a planar motor that comprises: a slider 16A, which is disposed on the substrate stage 2; and a stator 16B, which is disposed on the second base plate 14. The planar motor, which is capable of moving the substrate stage 2, is disclosed in, for example, U.S. Pat. No. 6,452,292, The substrate stage 2 is capable of moving in six directions the X axial, Y axial, Z axial, θX, θY, and θZ directions—by the operation of the drive system 16.

The substrate stage 2 has an upper surface 17, which is disposed around the substrate holding part 13 and is capable of opposing the emergent surface 11. In the present embodiment, as disclosed in U.S. Patent Application Publication No. 2007/0177125, the substrate stage 2 comprises a plate member holding part 18, which is disposed at least partly around the substrate holding part 13 and releasably holds a lower surface of a plate member T. In the present embodiment, the upper surface 17 of the substrate stage 2 includes an upper surface of the plate member T. The upper surface 17 is flat.

In the present embodiment, the substrate holding part 13 is capable of holding the substrate P such that the front surface thereof is substantially parallel to the XY plane. The plate member holding part 18 can hold the plate member T such that the upper surface 17 of the plate member T is substantially parallel to the XY plane.

The interferometer system 3 comprises: a first interferometer unit 3A, which is capable of optically measuring the position of the mask stage 1 (i.e., the mask M) within the XY plane; and a second interferometer unit 3B, which is capable of optically measuring the position of the substrate stage 2 (i.e., the substrate P) within the XY plane. When an exposing process is performed on the substrate P or a prescribed measuring process is performed, the control apparatus 5 controls the positions of the mask stage 1 (i.e., the mask M) and the substrate stage 2 (i.e., the substrate P) by driving the drive systems 9, 16 based on the measurement results of the interferometer system 3.

The liquid immersion member 4 is disposed at least partly around the optical path of the exposure light EL. In the present embodiment, at least part of the liquid immersion member 4 is disposed at least partly around the last optical element 12. The liquid immersion member 4 has a lower surface 20, which is capable of opposing a front surface of an object that is disposed at a position at which it opposes the emergent surface 11. The liquid immersion member 4 forms the immersion space LS such that the optical path of the exposure light EL between the emergent surface 11 and the object, which is disposed at a position at which it opposes the emergent surface 11, is filled with the second liquid LQ2. The second liquid LQ2 is held between at least part of the lower surface 20 and the front surface (i.e., the upper surface) of the object, and the immersion space LS is thereby formed.

The immersion space LS is a portion (space or area) that is filled with the second liquid LQ2. In the present embodiment, the object includes either the substrate stage 2 (i.e., the plate member T) or the substrate P, which is held by the substrate stage 2, or both. During an exposure of the substrate P, the liquid immersion member 4 forms the immersion space LS such that the optical path of the exposure light EL between the last optical element 12 and the substrate P is filled with the second liquid LQ2.

The exposure apparatus EX of the present embodiment is a scanning type exposure apparatus (i.e., a so-called scanning stepper) that projects the image of the pattern of the mask M to the substrate P while synchronously moving the mask M and the substrate P in prescribed scanning directions. When the substrate P is to be exposed, the control apparatus 5 controls the mask stage 1 and the substrate stage 2 so as to move the mask M and the substrate P in the prescribed scanning directions within the XY plane, which intersects the optical axis AX (i.e., the optical path of the exposure light EL). In the present embodiment, the scanning directions (i.e., the synchronous movement directions) of both the substrate P and the mask M are the Y axial directions. The control apparatus 5 both moves the substrate P in one of the Y axial directions with respect to the projection area PR of the projection optical system PL and radiates the exposure light EL to the substrate P through the projection optical system PL and the second liquid LQ2 of the immersion space LS on the substrate P while, at the same time, moving the mask M in the other Y axial direction with respect to the illumination area IR of the illumination system IL such that this movement is synchronized with the movement of the substrate P. Thereby, the image of the pattern of the mask M is projected to the substrate P, which is thereby exposed by the exposure light EL.

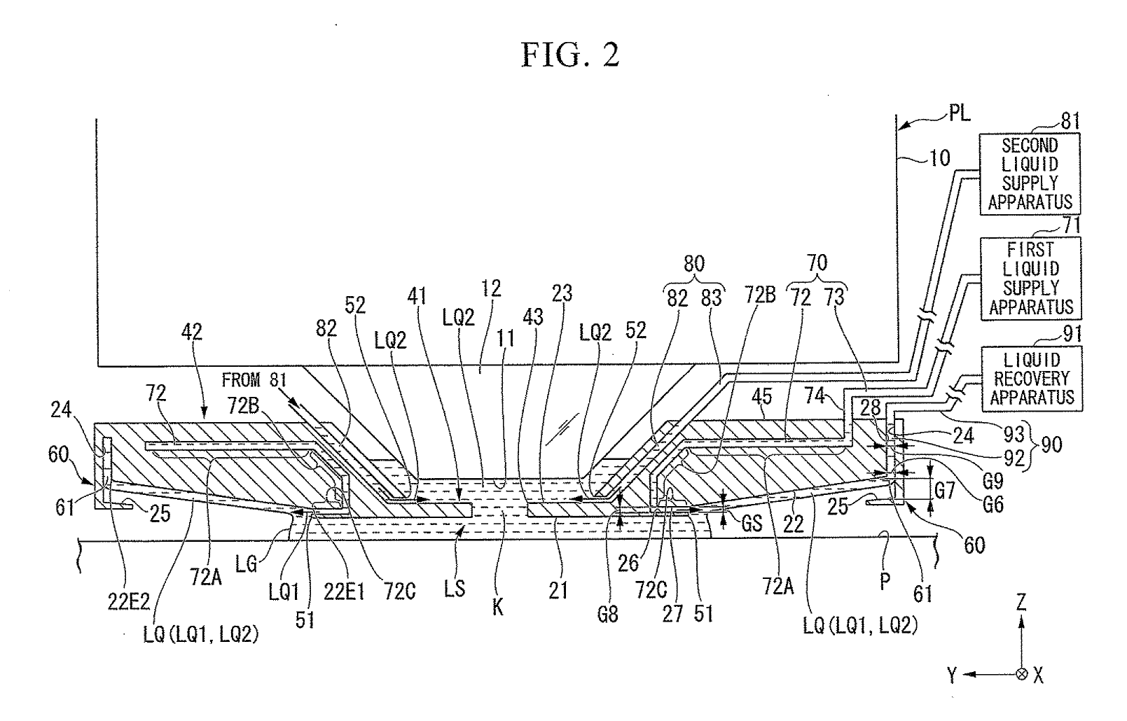

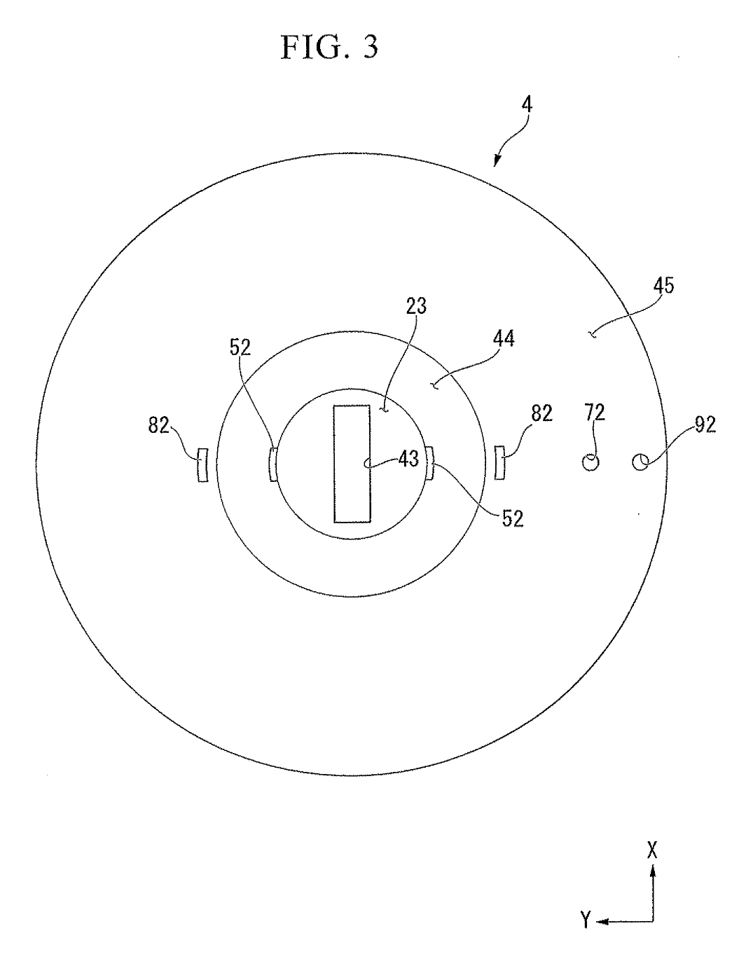

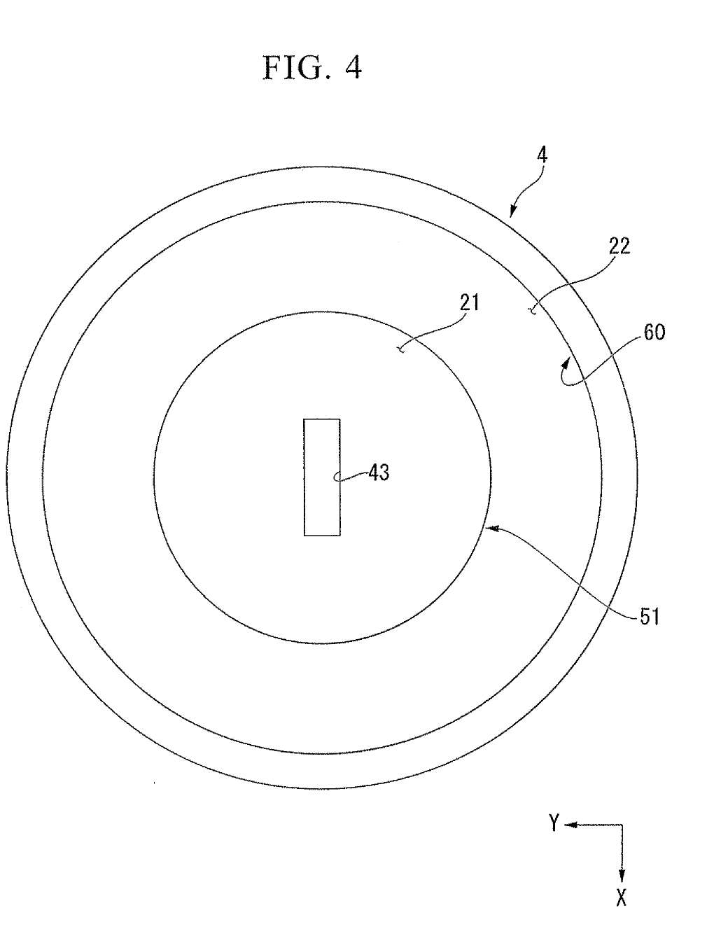

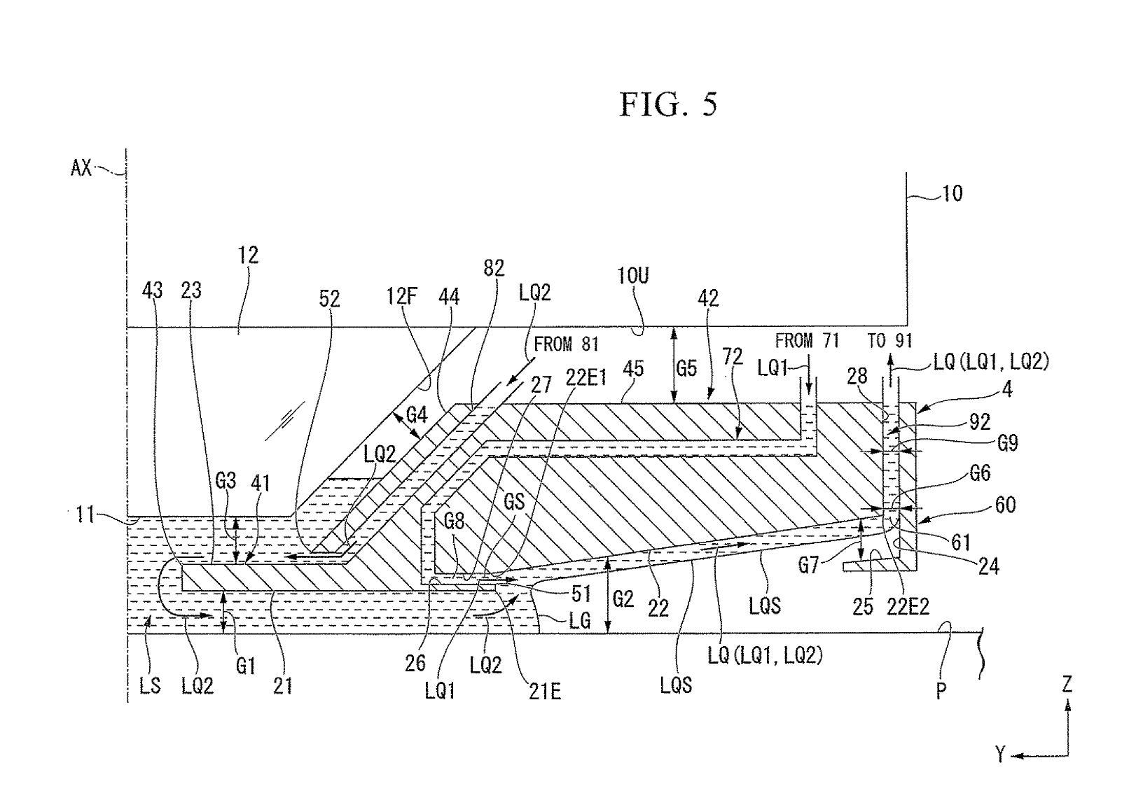

The following text explains the liquid immersion member 4, referencing FIG. 2 through FIG. 5. FIG. 2 is a side cross sectional view that shows the vicinity of the liquid immersion member 4, FIG. 3 is a view from above that shows the liquid immersion member 4, FIG. 4 is a view from below that shows the liquid immersion member 4, and FIG. 5 is a partial enlarged view of FIG. 2.

In the present embodiment, the liquid immersion member 4 is an annular member. At least part of the liquid immersion member 4 is disposed around part of the optical path of the exposure light EL and around the last optical element 12. As shown in FIG. 3 and FIG. 4, in the present embodiment, the external shape of the liquid immersion member 4 within the XY plane is circular. Furthermore, the external shape of the liquid immersion member 4 may be some other shape (e.g., rectangular).

In the present embodiment, the liquid immersion member 4 comprises a plate part 41, at least part of which is disposed such that it opposes the emergent surface 11, and a main body part 42, at least part of which is disposed around the last optical element 12.

The liquid immersion member 4 has: a first surface 21, which is disposed at least partly around an optical path K of the exposure light EL that emerges from the emergent surface 11 of the projection optical system PL; a second surface 22, which is disposed at least partly around the first surface 21; and a first supply port 51, which is disposed such that, at least partly around the first surface 21, it faces outward in the radial directions (faces in the outward radial direction) with respect to the optical axis AX of the projection optical system PL and supplies the first liquid LQ1 to the second surface 22. In the present embodiment, the lower surface 20 of the liquid immersion member 4 includes the first surface 21 and the second surface 22.

In addition, in the present embodiment, the liquid immersion member 4 has second supply ports 52, which supply the second liquid LQ2 to the optical path K of the exposure light EL that emerges from the emergent surface 11.

In the present embodiment, the first liquid LQ1 and the second liquid LQ2 are the same type of liquid. In the present embodiment, water (i.e., pure water) is used for the first liquid LQ1 and the second liquid LQ2. In the explanation below, the first liquid LQ1 and the second liquid LQ2 are generically called a liquid LQ where appropriate.

In the present embodiment, the first surface 21 is disposed around the optical path K of the exposure light EL that emerges from the emergent surface 11. The second surface 22 is disposed around the first surface 21. In the present embodiment, the external shapes of the first surface 21 and the second surface 22 within the XY plane are circular. In addition, an edge 22E1 on the inner side of the second surface 22 within the XY plane is also circular. In the present embodiment, at least part of the first surface 21 is disposed on the plate part 41 and the second surface 22 is disposed on the main body part 42.

In addition, the liquid immersion member 4 has a third surface 23, which faces a direction opposite that of the first surface 21 and is disposed around the optical path K of the exposure light EL such that at least part of it opposes the emergent surface 11. The third surface 23 is disposed on the plate part 41.

The plate part 41 of the liquid immersion member 4 has an opening 43 wherethrough the exposure light EL that emerges from the emergent surface 11 can pass. The first surface 21 and the third surface 23 are formed around the opening 43. During an exposure of the substrate P, the exposure light EL that emerges from the emergent surface 11 transits the opening 43 and is radiated to the front surface of the substrate P. As shown in FIG. 3 and FIG. 4, in the present embodiment, the opening 43 is long in the X axial directions, which intersect the scanning directions (i.e., the Y axial directions) of the substrate P.

The emergent surface 11, the first surface 21, and the second surface 22 are capable of opposing the front surface (i.e., the upper surface) of the object disposed below the liquid immersion member 4. During at least part of the exposure of the substrate P, the emergent surface 11, the first surface 21, and the second surface 22 oppose the front surface of the substrate P. Furthermore, the state wherein the first surface 21 and the front surface of the substrate P are opposed includes the state wherein the second liquid LQ2 exists between the first surface 21 and the front surface of the substrate P. In addition, the state wherein the second surface 22 and the substrate P are opposed includes the state wherein the flow of the liquid LQ (i.e., a liquid surface LQS discussed below) is formed between the second surface 22 and the substrate P.

The first surface 21 is capable of opposing the front surface of the object (i.e., the front surface of the substrate P, the upper surface of the plate member T, and the like) across a gap G1. The second surface 22 is capable of opposing the front surface of the object across a gap G2. The third surface 23 opposes the emergent surface 11 across a gap G3. In the present embodiment, the second surface 22 is disposed above the first surface 21. In the present embodiment, the gap G2 is larger than the gap G1.

In the present embodiment, the first surface 21 is substantially parallel to the XY plane. The second surface 22 is inclined upward toward the outer side in the radial directions with respect to the optical axis AX. Namely, the second surface 22 is inclined with respect to the first surface 21. In addition, the third surface 23 is substantially parallel to the first surface 21. In the present embodiment, the third surface 23 and the emergent surface 11 are substantially parallel.

The main body part 42 of the liquid immersion member 4 has: an inner side surface 44, which opposes at least part of a side surface 12F of the last optical element 12 across a gap G4; and an upper surface 45, which opposes a lower surface 10U of the holding member 10 across a gap G5. The side surface 12F is a surface that differs from the emergent surface 11 and wherethrough the exposure light EL does not pass. The side surface 12F is disposed around the emergent surface 11. Furthermore, at least part of the inner side surface 44 may oppose part of the holding member 10. Alternatively, at least part of the upper surface 45 may oppose part of the last optical element 12.

The first supply port 51 supplies the first liquid LQ1 such that the first liquid LQ1 flows over the second surface 22 to the outer side in the radial directions with respect to the optical axis AX. The first supply port 51 supplies the first liquid LQ1 such that, while contacting the second surface 22, the first liquid LQ1 flows over the second surface 22 to the outer side in the radial directions with respect to the optical axis AX.

In the present embodiment, the first supply port 51 is disposed between an outer side edge 21E, which is defined by the external shape of the first surface 21, and the edge 22E1 on the inner side of the second surface 22. Namely, in the present embodiment, the first supply port 51 is disposed above the first surface 21 and below the second surface 22.

In the present embodiment, the first supply port 51 is a slit opening that is formed such that it surrounds the optical path of the exposure light EL. The first supply port 51 is disposed such that it follows along the edge 22E1 on the inner side of the second surface 22. A size GS (i.e., a slit width) of the first supply port 51 in the Z axial directions is sufficiently small. During an exposure of the substrate P, the size GS of the first supply port 51 is smaller than, for example, the gap G1.

The second supply ports 52 supply the second liquid LQ2 to a gap between the liquid immersion member 4 and the last optical element 12. In the present embodiment, the second supply ports 52 are disposed at prescribed regions of the liquid immersion member 4 such that they face the optical path K of the exposure light EL that emerges from the emergent surface 11. In the present embodiment, the second supply ports 52 supply the second liquid LQ2 to the space between the emergent surface 11 and the third surface 23. In the present embodiment, the second supply ports 52 are disposed in the inner side surface 44. As shown in FIG. 3, in the present embodiment, the second supply ports 52 are disposed on the +Y side and the −Y side of the opening 43 (i.e., the optical path of the exposure light EL). Furthermore, the second supply ports 52 may be disposed on the +X side and the −X side of the opening 43 (i.e., the optical path of the exposure light EL). In addition, the number of the second supply ports 52 is not limited to two. The second supply ports 52 may be disposed at three or more positions around the optical path of the exposure light EL.

The second liquid LQ2 that is supplied via the second supply ports 52 is supplied to the optical path of the exposure light EL that emerges from the emergent surface 11. Thereby, the optical path of the exposure light EL is filled with the second liquid LQ2. In addition, during at least part of the exposure of the substrate P, the front surface of the substrate P opposes the emergent surface 11, the first surface 21, and the second surface 22. During at least part of the exposure of the substrate P, at least some of the second liquid LQ2 supplied via the second supply ports 52 to the space between the emergent surface 11 and the third surface 23 is supplied via the opening 43 to the space between the first surface 21 and the front surface of the substrate P, and thereby the optical path of the exposure light EL between the emergent surface 11 and the front surface of the substrate P is filled with the second liquid LQ2. In addition, at least some of the second liquid LQ2 is held between the first surface 21 and the front surface of the substrate P. The substrate P is exposed with the exposure light EL that emerges from the emergent surface 11 and transits the second liquid LQ2 between the emergent surface 11 and the front surface of the substrate P.

In the present embodiment, part of the immersion space LS is formed from the second liquid LQ2 held between the first surface 21 and the object. In the present embodiment, when the substrate P is irradiated with the exposure light EL, the immersion space LS is already formed such that part of the area of the front surface of the substrate P that includes the projection area PR is covered with the second liquid LQ2. The exposure apparatus EX of the present embodiment adopts a local liquid immersion system.

For the sake of simplicity, the following text explains an exemplary case wherein: the substrate P is disposed at a position at which it opposes the emergent surface 11, the first surface 21, and the second surface 22; the second liquid LQ2 is held between the liquid immersion member 4 and the substrate P; and thereby the immersion space LS is formed. Furthermore, as discussed above, the immersion space LS can be formed between the emergent surface 11 and the liquid immersion member 4 on one side and another member (e.g., the plate member T of the substrate stage 2) on the other side.

In the present embodiment, the immersion space LS is formed between at least part of the emergent surface 11, the first surface 21, and the second surface 22 on one side and the front surface of the substrate P on the other side with at least some of the second liquid LQ2 supplied via the second supply ports 52 such that the optical path of the exposure light EL between the emergent surface 11 and the substrate P is filled with the second liquid LQ2.

In FIG. 2 and FIG. 5, an air-liquid interface LG (i.e., a meniscus or edge) of the second liquid LQ2 of the immersion space LS is formed between the second surface 22 and the front surface of the substrate P. Namely, the immersion space LS is formed such that the first supply port 51 contacts the second liquid LQ2 of the immersion space LS that is formed with the second liquid LQ2 supplied via the second supply ports 52. In FIG. 2 and FIG. 5, the first liquid LQ1 is supplied via the first supply port 51 to the second surface 22 in the state wherein the first supply port 51 is immersed in the second liquid LQ2 of the immersion space LS.

The second surface 22 is preferably lyophilic with respect to the first liquid LQ1. In the present embodiment, the contact angle of the first liquid LQ1 with respect to the second surface 22 is less than 90°. In the present embodiment, the second surface 22 is made of titanium and is lyophilic (i.e., hydrophilic) with respect to the first liquid LQ1.

In the present embodiment, the second surface 22 is preferably more lyophilic than the front surface of the object (e.g., the substrate P) that opposes the second surface 22. Furthermore, a film that is formed from a material that is lyophilic with respect to the first liquid LQ1 may be formed on at least part of the lower surface 20 of the liquid immersion member 4, and the second surface 22 may be made lyophilic with respect to the first liquid LQ1. In addition, the second surface 22 does not have to be lyophilic with respect to the first liquid LQ1.

In the present embodiment, the first liquid LQ1 is supplied via the first supply port 51 in parallel with the supply of the second liquid LQ2 via the second supply ports 52. Namely, the first liquid LQ1 is supplied via the first supply port 51 to the second surface 22 in the state wherein the immersion space LS of the second liquid LQ2 is formed, and the first liquid LQ1 supplied via the first supply port 51 flows over the second surface 22 toward the outer side in the radial directions with respect to the optical axis AX. In addition, at least some of the second liquid LQ2 of the immersion space LS flows, together with the first liquid LQ1 supplied via the first supply port 51, over the second surface 22 toward the outer side in the radial directions. Thereby, on the outer side of the interface LG of the immersion space LS in the radial directions with respect to the optical axis AX, the liquid LQ (i.e., the first liquid LQ1, the second liquid LQ2, or both) flows over the second surface 22 toward the outer side in the radial directions with respect to the optical axis AX without contacting the front surface of the substrate P (i.e., the object). Namely, on the outer side of the interface LG of the immersion space LS in the radial directions with respect to the optical axis AX, a gas space exists between the surface of the liquid LQ (i.e., the liquid surface LQS) that flows over the second surface 22 and the front surface of the substrate P (i.e., the object) that opposes such.

In addition, the liquid immersion member 4 comprises a recovery part 60, which is disposed on the outer side of the second surface 22 in the radial directions with respect to the optical axis AX and recovers at least some of the liquid LQ (i.e., the first liquid LQ1, the second liquid LQ2, or both) on the second surface 22. The recovery part 60 is capable of recovering the first liquid LQ1, which is supplied via the first supply port 51 and flows over the second surface 22, and the second liquid LQ2, which flows over the second surface 22 together with the first liquid LQ1.

In the present embodiment, the recovery part 60 has a fourth surface 24, which is disposed such that it intersects the second surface 22. A gap G6 is formed between an edge 22E2 on the outer side of the second surface 22 and the fourth surface 24. The recovery part 60 recovers at least some of the liquid LQ that flows from the second surface 22 into the gap G6.

In addition, in the present embodiment, at least part of the fourth surface 24 is disposed lower than (i.e., on the −Z side of) the edge 22E2 on the outer side of the second surface 22 such that it faces the optical axis AX. In the present embodiment, the fourth surface 24 is disposed substantially parallel to the optical axis AX.

In addition, in the present embodiment, the recovery part 60 has a fifth surface 25, which is connected to a lower end of the fourth surface 24 and is disposed such that it opposes a circumferential edge area of the second surface 22 across a gap G7. The fifth surface 25 is disposed below the circumferential edge area of the second surface 22 such that it faces upward (i.e., in the +Z direction).

In the present embodiment, the fourth surface 24 is disposed annularly around the first surface 22. In addition, the fifth surface 25 is annular within the XY plane.

In the present embodiment, the gap G6 between the edge 22E2 on the outer side of the second surface 22 and the fourth surface 24 comprises a recovery port 61 of the recovery part 60 that is capable of recovering at least some of the liquid LQ on the second surface 22. In the present embodiment, the shape of the recovery port 61 within the XY plane is annular. Furthermore, multiple recovery ports 61 may be disposed within the XY plane at prescribed intervals around the optical path of the exposure light EL. Furthermore, in the present embodiment, the fifth surface 25, which prevents the liquid LQ from falling from the vicinity of the recovery port 61 onto the front surface of the substrate P (i.e., the object), is provided, but may be omitted.

As shown in FIG. 2, the first supply port 51 is connected to a first liquid supply apparatus 71 via a supply passageway 70. The supply passageway 70 comprises an internal passageway 72 of the liquid immersion member 4 and a supply pipe passageway 73, which connects the internal passageway 72 and the first liquid supply apparatus 71. The first liquid supply apparatus 71 can supply the first liquid LQ1, which is clean and the temperature of which is adjusted, to the first supply port 51.

In the present embodiment, an inflow port 74 of the internal passageway 72 is disposed in the upper surface 45 of the liquid immersion member 4. The first liquid LQ1 supplied from the first liquid supply apparatus 71 flows into the internal passageway 72 via the inflow port 74. The internal passageway 72 comprises a first portion 72A, which extends from the inflow port 74 toward the inner side in the radial directions, a second portion 72B, which is connected to the first portion 72A and at least part of which is bent, and a third portion 72C, which extends from the lower end of the second portion 72B toward the outer side in the radial directions (in the inward radial direction) such that it connects the second portion 72B and the first supply port 51. In the present embodiment, the internal passageway 72, which comprises the first portion 72A, the second portion 72B, and the third portion 72C, is formed such that it surrounds the optical axis AX.

The third portion 72C is formed between a sixth surface 26, which faces a direction (i.e., the +Z direction) that is opposite that of the first surface 21, and a seventh surface 27, which opposes the sixth surface 26 across a gap G8. In the present embodiment, the sixth surface 26 and the seventh surface 27 are substantially parallel to the XY plane and the gap G8 and the size GS are substantially equal. Furthermore, the sixth surface 26 and the seventh surface 27 may be inclined with respect to the XY plane so that they are aligned with the second surface 22. For example, the sixth surface 26 and the seventh surface 27 may be inclined upward toward the outer side in the radial directions with respect to the optical axis AX. In addition, the sixth surface 26 and the seventh surface 27 do not have to be parallel. For example, the sixth surface 26 and the seventh surface 27 may be disposed at an angle with respect to one another such that the size GS is smaller than the gap G8.

The first liquid LQ1 that flows from the inflow port 74 into the internal passageway 72 spreads and flows in the first portion 72A such that it surrounds the optical axis AX and flows into the third portion 72C via the second portion 72B. The first liquid LQ1 that flows into the third portion 72C flows toward the outer side thereof in the radial directions and is supplied to the first supply port 51. The first supply port 51 supplies the first liquid LQ1 from the third portion 72C to the second surface 22 such that the first liquid LQ1 flows over the second surface 22 toward the outer side in the radial directions. The first supply port 51 supplies the first liquid LQ1 to the second surface 22 such that substantially the entire area thereof is wetted with the first liquid LQ1.

In addition, as shown in FIG. 2, the second supply ports 52 are connected to a second liquid supply apparatus 81 via supply passageways 80. Each of the supply passageways 80 comprises an internal passageway 82 of the liquid immersion member 4 and a supply pipe passageway 83, which connects the internal passageway 82 and the second liquid supply apparatus 81. The second liquid supply apparatus 81 can supply the second liquid LQ2, which is clean and the temperature of which is adjusted, to the second supply ports 52.

In addition, as shown in FIG. 2, the recovery port 61 is connected to a liquid supply apparatus 91 via a recovery passageway 90. In the present embodiment, the recovery passageway 90 comprises an internal passageway 92 of the liquid immersion member 4 and a recovery pipe passageway 93, which connects the internal passageway 92 and the liquid recovery apparatus 91. At least part of the internal passageway 92 is formed between the fourth surface 24 and an eighth surface 28, which opposes the fourth surface 24 across a gap G9. The liquid recovery apparatus 91 comprises a vacuum system (such as a valve that controls the connection state between a vacuum source and the recovery port 61) and is capable of suctioning and recovering the liquid LQ via the recovery port 61.

The following explains a method of using the exposure apparatus EX that has the abovementioned configuration to expose the substrate P.

First, the control apparatus 5 causes the first surface 21 and the second surface 22 on one side and the front surface of the substrate P (or the upper surface 17 of the substrate stage 2) on the other side to oppose one another. The first surface 21 and the front surface of the substrate P are opposed to one another across the gap G1, and the second surface 22 and the front surface of the substrate P are opposed to one another across the gap G2.

The control apparatus 5 feeds the second liquid LQ2 from the second liquid supply apparatus 81 in the state wherein the first surface 21 and the second surface 22 on one side and the front surface of the substrate P on the other side are caused to oppose one another.

The second liquid LQ2 fed from the second liquid supply apparatus 81 is supplied via the second supply ports 52 to the space between the emergent surface 11 and the third surface 23 and is supplied to the optical path of the exposure light EL that emerges from the emergent surface 11. Thereby, the optical path of the exposure light EL is filled with the liquid LQ.

In addition, at least some of the second liquid LQ2 supplied via the second supply ports 52 is supplied via the opening 43 to the space between the first surface 21 and the front surface of the substrate P and is held therebetween. In addition, at least some of the second liquid LQ2 is held between the second surface 22 and the front surface of the substrate P. Thereby, the second liquid LQ2 supplied via the second supply ports 52 forms the immersion space LS between at least part of the emergent surface 11, the first surface 21, and the second surface 22 on one side and the front surface of the substrate P on the other side such that the optical path of the exposure light EL between the emergent surface 11 and the substrate P is filled with the second liquid LQ2.

In addition, the control apparatus 5 feeds the first liquid LQ1 supplied by the first liquid supply apparatus 71. In addition, the control apparatus 5 operates the liquid recovery apparatus 91. The first liquid LQ1 fed from the first liquid supply apparatus 71 is supplied to the first supply port 51 via the supply passageway 70. The first supply port 51 supplies the first liquid LQ1 to the second surface 22.

The control apparatus 5 controls the first liquid supply apparatus 71 and the second liquid supply apparatus 81 such that the supply of the first liquid LQ1 via the first supply port 51 and the supply of the second liquid LQ2 via the second supply ports 52 are performed in parallel. Namely, the control apparatus 5 supplies the first liquid LQ1 via the first supply port 51 in the state wherein the immersion space LS is formed with the second liquid LQ2 supplied via the second supply ports 52.

When the first liquid LQ1 is supplied via the first supply port 51, it flows over the second surface 22 toward the outer side in the radial directions; in addition, at least some of the second liquid LQ2 of the immersion space LS flows, together with the first liquid LQ1 supplied via the first supply port 51, over the second surface 22 toward the outer side in the radial directions. The control apparatus 5 supplies the first liquid LQ1 via the first supply port 51 such that the gas space is formed between the surface (i.e., the liquid surface LQS) of the liquid LQ that flows over the second surface 22 and the front surface of the substrate P (i.e., the object). Thereby, the liquid surface LQS of the liquid LQ, which flows toward the outer side in the radial directions with respect to the optical axis AX, is formed on the outer side of the first surface 21 in the radial directions with respect to the optical axis AX (i.e., on the outer side of the interface LG of the immersion space LS). The liquid LQ (i.e., the first and second liquids LQ1, LQ2) that flows over the second surface 22 toward the outer side in the radial directions is recovered by the recovery part 60. At least some of the liquid LQ that flows on the second surface 22 is recovered via the recovery port 61.

While flowing the liquid LQ along the second surface 22 by supplying the first liquid LQ1 via the first supply port 51 and the second liquid LQ2 via the second supply ports 52 in parallel with the recovery of the liquid LQ via the recovery part 60 (i.e., the recovery port 61), the control apparatus 5 forms the immersion space LS such that the optical path of the exposure light EL between the emergent surface 11 and the substrate P is filled with the second liquid LQ2.

While supplying the second liquid LQ2 via the second supply ports 52 in parallel with the supply of the first liquid LQ1 via the first supply port 51, the control apparatus 5 starts the exposure of the substrate P in the state wherein the immersion space LS is formed such that part of the front surface of the substrate P is locally covered with the second liquid LQ2.

The control apparatus 5 illuminates the mask M with the exposure light EL by causing the illumination system IL to emit the exposure light EL. The exposure light EL that emerges from the mask M emerges from the emergent surface 11 of the projection optical system PL. The control apparatus 5 exposes the substrate P with the exposure light EL that emerges from the emergent surface 11 and transits the second liquid LQ2 between the emergent surface 11 and the substrate P. Thereby, the image of the pattern of the mask M is projected to the substrate P, which is thereby exposed with the exposure light EL. During the exposure of the substrate P as well, the first liquid LQ1 is supplied via the first supply port 51 in parallel with the supply of the second liquid LQ2 via the second supply ports 52.

As discussed above, the exposure apparatus EX of the present embodiment is a scanning type exposure apparatus wherein the substrate P is moved in prescribed directions within the XY plane in the state wherein the second liquid LQ2 is held between the emergent surface 11 and the substrate P (i.e., in the state wherein the immersion space LS is formed) during at least part of the exposure of the substrate P. For example, during the radiation of the exposure light EL to the substrate P (i.e., during the scanning exposure), the substrate P moves in the Y axial directions with respect to the last optical element 12 and the liquid immersion member 4. In addition, if multiple shot regions on the substrate P are sequentially exposed, then, when a second shot region is to be exposed after the exposure of a first shot region, the substrate P is moved in, for example, one of the X axial directions with respect to the last optical element 12 and the liquid immersion member 4 or a direction that is inclined with respect to the X axis within the XY plane (i.e., a stepping movement). In addition, the movement during a scanning exposure is not limited to a stepping motion; for example, it is also possible for the substrate P to move under various movement conditions in the state wherein the second liquid LQ2 is held between the substrate P and the emergent surface 11.

The movement conditions of the substrate P include at least a movement velocity and an acceleration (or a deceleration) in a prescribed direction (e.g., the −Y direction) within the XY plane and a movement distance (i.e., when moving from a first position to a second position within the XY plane).

In the present embodiment, the first liquid LQ1 supplied via the first supply port 51 flows over the second surface 22 toward the outer side in the radial directions with respect to the optical axis AX; therefore, even if, for example, the substrate P moves at a high speed or a high acceleration, it is possible to prevent the second liquid LQ2 from, for example, leaking out of the space between the liquid immersion member 4 and the substrate P, or forming a film, a drop, or the like and remaining on the substrate P.

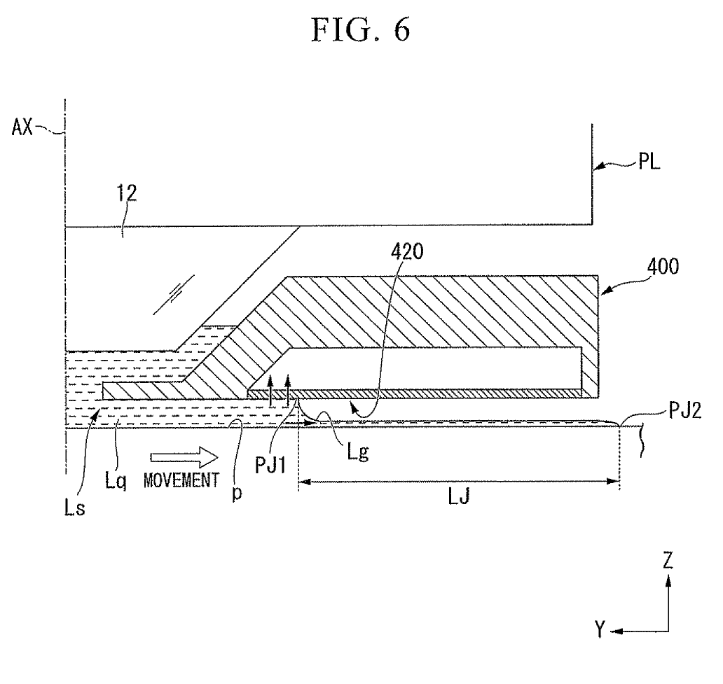

FIG. 6 is a schematic drawing that shows the behavior of the immersion space Ls when a liquid immersion member 400 according to a comparative example is used. The first supply port (51) is not provided to the liquid immersion member 400. If the substrate P is moved at high speed in the −Y direction in the state wherein a liquid Lq is held between the last optical element 12 and the liquid immersion member 400 on one side and the front surface of a substrate p on the other side, then there is a possibility that at least part of the liquid Lq that forms an immersion space Ls will form a film on the substrate p. Namely, in the comparative example shown in FIG. 6, there is a possibility that the movement of the substrate p in the −Y direction will increase a distance LJ (i.e., an amount of deviation) between a position PJ1 of an upper end of an air-liquid interface Lg of the liquid Lq (i.e., the intersection between the air-liquid interface Lg and a lower surface 420 of the liquid immersion member 400) and a position P32 of a lower end of the air-liquid interface Lg (i.e., the intersection between the air-liquid interface Lg and the front surface of the substrate p) in the radial directions with respect to the optical axis AX. As a result, there is an increased possibility that the liquid Lq will, for example, leak out of the space between the liquid immersion member 400 and the front surface of the substrate P or form a film, a drop, or the like and remain on the substrate p.

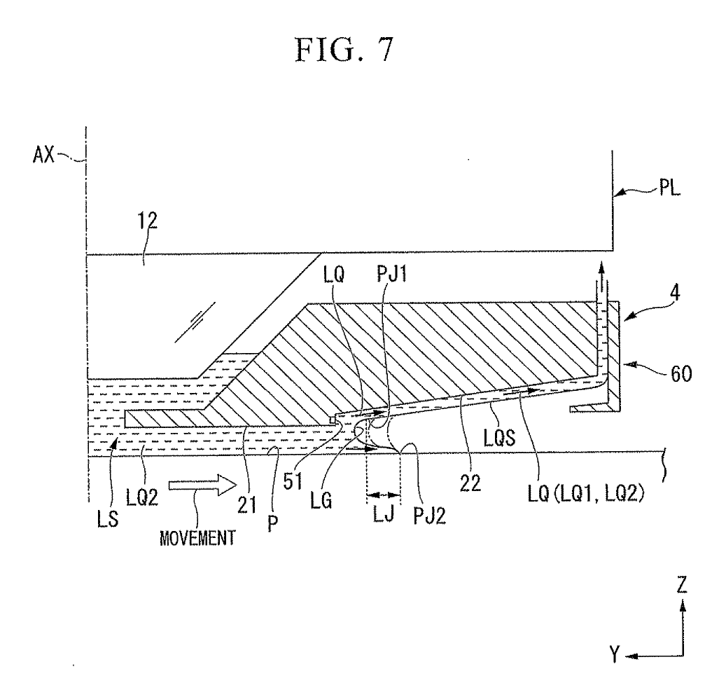

FIG. 7 is a schematic drawing for explaining the behavior of the immersion space LS in the case wherein the liquid immersion member 4 according to the present embodiment is used. The first supply port 51, which faces toward the outer side in the radial directions with respect to the optical axis AX, is provided and the liquid LQ flows over the second surface 22 toward the outer side in the radial directions with respect to the optical axis AX, which prevents at least some of the second liquid LQ2 that forms the immersion space LS from, for example, leaking out of the space between the liquid immersion member 4 and the front surface of the substrate P or forming a film, a drop, or the like and remaining on the substrate P. Namely, the liquid surface LQS of the liquid LQ that flows toward the outer side in the radial directions with respect to the optical axis AX is formed on the outer side of the interface LG in the radial directions with respect to the optical axis AX, and therefore it is possible to prevent the second liquid LQ2 from remaining on the front surface of the substrate P, which opposes the liquid surface LQS. For example, even if the position PJ2 of the lower end of the air-liquid interface LG of the second liquid LQ2 moves in the −Y direction by the movement of the substrate P in the −Y direction, the first liquid LQ1 moves in the −Y direction over the second surface 22 and the position PJ1 of the upper end of the air-liquid interface LG formed on the liquid LQ that flows over the second surface 22 is also displaced smoothly in the −Y direction, which makes it possible to prevent the distance LJ (i.e., the amount of deviation) between the position PJ1 of the upper end of the air-liquid interface LG of the second liquid LQ2 and the position PJ2 of the lower end of the air-liquid interface LG from increasing. Accordingly, even if the substrate P moves, the formation of a thin film of the second liquid LQ2 on the substrate P is prevented. Accordingly, it is also possible to prevent the second liquid LQ2 from leaking out, remaining behind, and the like.

Furthermore, in the present embodiment, the velocity of the flow of the liquid LQ formed over the second surface 22 is greater than the movement velocity of the substrate P (i.e., the object), which is opposite that of the flow of the liquid LQ (i.e., the liquid surface LQS). However, it may be equal to or less than the movement velocity of the substrate P (i.e., the object).

Furthermore, the supply conditions of the first liquid LQ1 supplied via the first supply port 51 may be adjusted in accordance with the movement conditions during the movement of the substrate P.

For example, the flow speed of the first liquid LQ1 that is supplied via the first supply port 51 is adjusted in accordance with the movement velocity of the substrate P in the prescribed direction (e.g., one of the Y axial directions) within the XY plane.

For example, if the substrate P is moved at high speed in the −Y direction, the flow speed of the first liquid LQ1 that is supplied in the −Y direction via the first supply port 51 is increased. For example, the flow speed of the first liquid LQ1 can be increased by adjusting the amount of the first liquid LQ1 that is supplied per unit of time by the first liquid supply apparatus 71. Adjusting the flow speed of the first liquid LQ1 in accordance with the movement velocity of the substrate P makes it possible to reduce the amount of deviation LJ between the position PJ1 and the position PJ2.

In addition, the flow speed of the first liquid LQ1, which is supplied substantially parallel to the Y axial directions via the first supply port 51, can be adjusted in accordance with the acceleration of the substrate P in the prescribed direction (e.g., one of the Y axial directions) within the XY plane. For example, if the substrate P is moved with a high acceleration in the −Y direction, then the flow speed of the first liquid LQ1 supplied in the −Y direction via the first supply port 51 is increased. In so doing, it is possible to reduce the amount of deviation LJ.

In addition, the flow speed of the first liquid LQ1, which is supplied substantially parallel to the Y axial directions via the first supply port 51, can be adjusted in accordance with the linear movement distance of the substrate P in the prescribed direction (e.g., one of the Y axial directions) within the XY plane.

Thus, adjusting, in accordance with the movement conditions of the substrate P, the supply conditions of the first liquid LQ1 supplied via the first supply port 51 in the same direction (i.e., the −Y direction) as the movement direction of the substrate P makes it possible to reduce the amount of deviation LJ between the position PJ1 and the position PJ2 and to prevent the second liquid LQ2 from leaking out, remaining behind, and the like.

Furthermore, the above explained a case wherein the immersion space LS of the second liquid LQ2 is formed on the substrate P, but the same applies also to cases wherein the immersion space LS of the second liquid LQ2 is formed on the substrate stage 2 (i.e., the plate member T) or wherein it spans the substrate stage 2 (i.e., the plate member 1) and the substrate P.

As explained above, according to the present embodiment, the first supply port 51, which is disposed such that it faces toward the outer side in the radial directions with respect to the optical axis AX and supplies the first liquid LQ1 to the second surface 22 of the liquid immersion member 4, is provided, which makes it possible to prevent the second liquid LQ2 from, for example, leaking out or remaining on the front surface of the object (i.e., the substrate P) that opposes the second surface 22. In addition, according to the present embodiment, the liquid surface LQS of the liquid LQ that flows toward the outer side in the radial directions with respect to the optical axis AX is formed on the second surface 22 of the liquid immersion member 4, which makes it possible to prevent the second liquid LQ2 from, for example, leaking out or remaining on the front surface of the object (e.g., the substrate P) that opposes the second surface 22. Accordingly, it is possible to prevent exposure failures from occurring while preventing a drop in throughput.

In addition, according to the present embodiment, the recovery part 60 has the fourth surface 24, which makes it possible to prevent the liquid LQ from leaking off of the second surface 22 and to satisfactorily recover the liquid LQ from the second surface 22 via the recovery port 61. In addition, the fifth surface 25 is provided, which makes it possible to prevent the liquid LQ in the circumferential edge area of the second surface 22 from falling onto the substrate P and the like. Furthermore, a porous member, such as mesh, may be disposed in the recovery port 61.

### Second Embodiment

The following text explains a second embodiment. In the explanation below, constituent parts that are identical or equivalent to those in the embodiment discussed above are assigned identical symbols and the explanations thereof are therefore abbreviated or omitted.

In the second embodiment, the second surface 22 is not inclined upward.

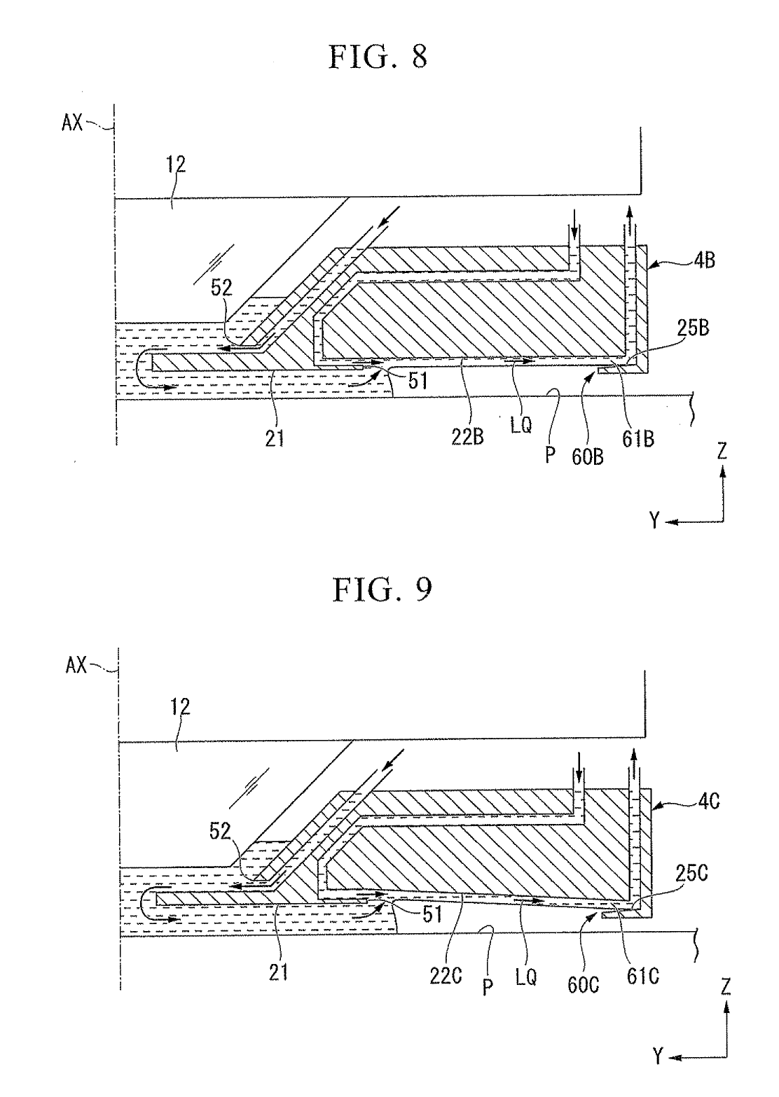

FIG. 8 shows one example of a liquid immersion member 4B according to the second embodiment. In FIG. 8, the liquid immersion member 413 has the first surface 21 and a second surface 22B. In the present embodiment, the first surface 21 and the second surface 22B are substantially parallel. The second surface 22B is substantially parallel to the XY plane and is lyophilic with respect to the first liquid LQ1. In the present embodiment as well, it is possible to prevent the second liquid LQ2 of the immersion space LS from leaking out, remaining behind, and the like using the first liquid LQ1 supplied via the first supply port 51.

In addition, as in a liquid immersion member 4C shown in FIG. 9, a second surface 22C may be inclined downward toward the outer side in the radial directions with respect to the optical axis AX.

In addition, in the examples shown in FIG. 8 and FIG. 9, a fifth surface (25B, 25C) is proximate to a circumferential edge of the second surface (i.e., the second surface 22B or a second surface 22C), and therefore a recovery port (61B, 61C) is formed between the fifth surface and the second surface. Namely, the recovery port (618, 61C), wherethrough the liquid LQ from the second surface (22B, 22C) is recovered, may face the optical axis AX. Namely, the recovery port wherethrough the liquid LQ from the second surface (22B, 22C) is recovered does not have to be oriented downward (i.e., in the −Z direction) as in the first embodiment.

### Third Embodiment

The following text explains a third embodiment. In the explanation below, constituent parts that are identical or equivalent to those in the embodiments discussed above are assigned identical symbols and the explanations thereof are therefore abbreviated or omitted.

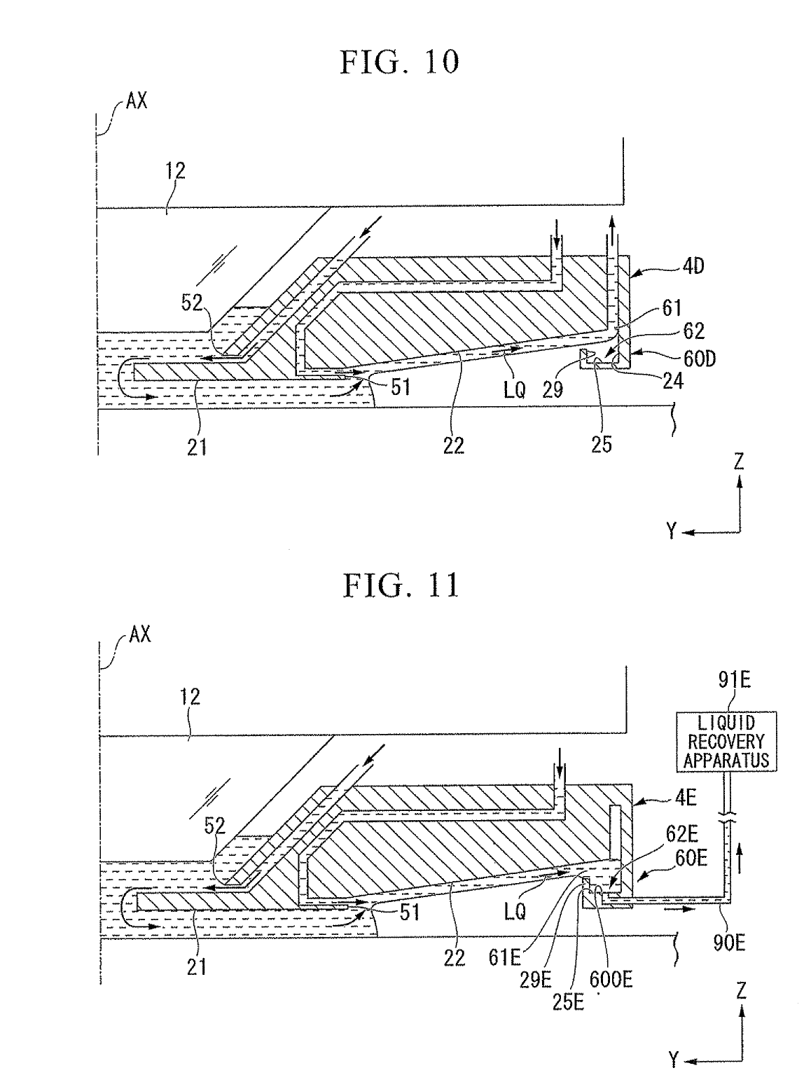

FIG. 10 is a view that shows one example of a liquid immersion member 4D according to the third embodiment. In FIG. 10, the liquid immersion member 4D comprises a recovery part 60D, which recovers at least some of the liquid LQ on the second surface 22. In the present embodiment, the recovery part 60D has a recessed part 62, which is disposed below a circumferential edge area of the second surface 22 such that it is oriented upward. The recessed part 62 is defined by the lower end of the fourth surface 24, the fifth surface 25, and a ninth surface 29, which is disposed such that it opposes the fourth surface 24. The recessed part 62 is annular within the XY plane.

Because the recessed part 62 is provided, the liquid LQ on the second surface 22 is prevented from leaking out, falling onto the substrate P, and the like.

A recovery part 60E shown in FIG. 11 is a modified example of the recovery part 60D shown in FIG. 10. In FIG. 11, the recovery part 60E has a recovery port 61E between an upper end of a ninth surface 29E and a second surface 22. In addition, a discharge port 600E, which discharges the liquid LQ that flows into the recessed part 62E from the second surface 22 is provided on the inner side of a recessed part 62E. The recessed part 62E can accumulate the liquid LQ. The liquid LQ on the second surface 22 can flow into the recessed part 62E via the recovery port 61E. The recovery part 60E discharges, via the discharge port 600E disposed in the recessed part 62E, at least some of the liquid LQ that flows into the recessed part 62E. In the example shown in FIG. 11, the recovery port 61E faces the optical axis AX and the discharge port 600E is disposed in a fifth surface 25E, which faces upward. The discharge port 600E is connected to a liquid recovery apparatus 91E via a recovery passageway 90E. The liquid recovery apparatus 91E recovers at least some of the liquid LQ that flows into the recessed part 62E via the discharge port 600E and the recovery passageway 90E.

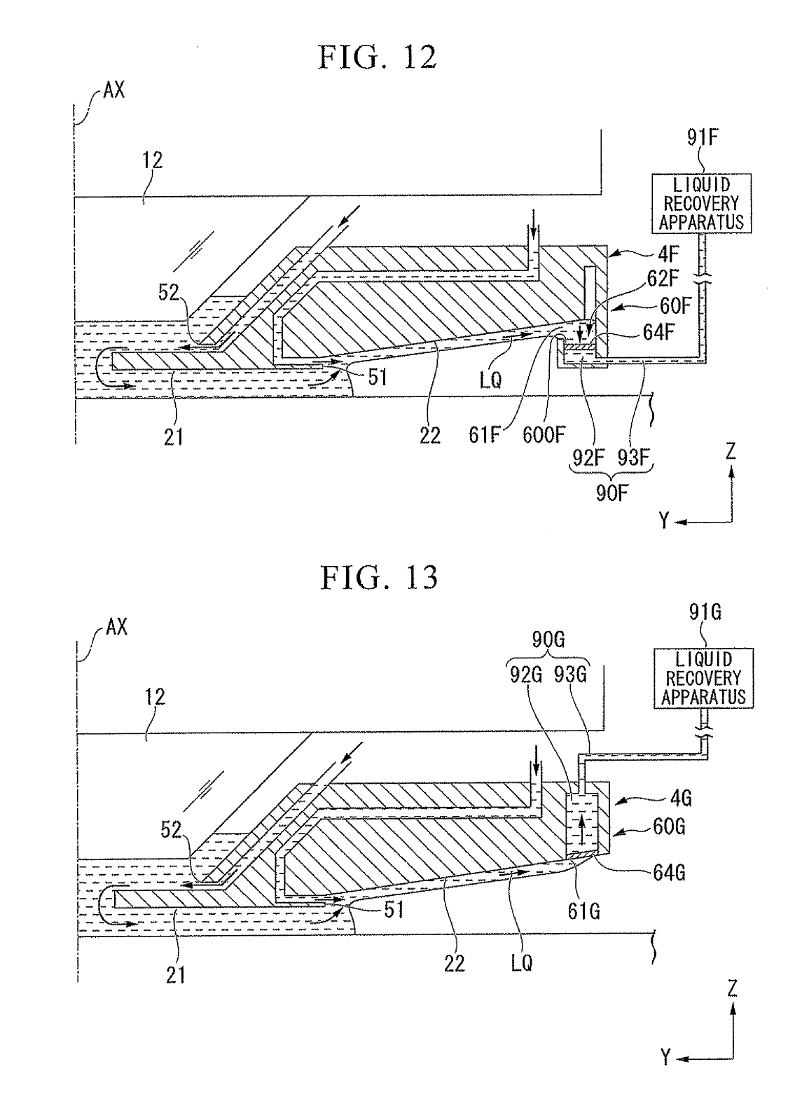

A recovery part 60F shown in FIG. 12 is a modified example of the recovery part 60E shown in FIG. 11. In FIG. 12, the recovery part 60F comprises a discharge port 600F, which is disposed on the inner side of a recessed part 62F and is capable of discharging at least some of the liquid LQ on the second surface 22, and a porous member 64F, which is disposed in the discharge port 600F. The discharge port 600F is connected to a liquid recovery apparatus 91F via a recovery passageway 90F.

By controlling the liquid recovery apparatus 91F, the control apparatus 5 can control the difference between a pressure in a space on the upper surface side and a pressure in a space on the lower surface side of the porous member 64F such that only the liquid LQ passes from the upper surface side space to the lower surface side space of the porous member 64F. The control apparatus 5 controls the difference between the pressure in the space on the upper surface side and the pressure in the space on the lower surface side of the porous member 64F by controlling the liquid recovery apparatus 91F such that only the liquid LQ passes from the upper surface side to the lower surface side of the porous member 64F; namely, the control apparatus 5 makes an adjustment such that only the liquid LQ is recovered from the second surface 22 via the holes of the porous member 64F and a gas does not pass therethrough. The technology for adjusting the pressure differential between the one side and the other side of the porous member 64F and passing only the liquid LQ from the one side to the other side of the porous member 64F is disclosed in, for example, U.S. Pat. No. 7,292,313.

Furthermore, in the embodiment of FIG. 11 and FIG. 12, the liquid LQ is recovered (discharged) via the recessed part (62E, 62F), but the gap G6 above the recessed part (62E, 62F) may jointly serve as a recovery port.

A recovery part 60G shown in FIG. 13 is a modified example of the recovery part 60 of the first embodiment. In FIG. 13, the recovery part 60G has a recovery port 61G which is disposed around the second surface 22 and is oriented downward (i.e., in the −Z direction), and comprises a porous member 64G, which is disposed in the recovery port 61G. On the outer side of the recovery port 61G in the radial directions with respect to the optical axis AX, the recovery part 60G does not have a surface (i.e., a wall) that extends downward (i.e., in the −Z direction) from the recovery port 61G. In the present embodiment, the porous member 64G is disposed in the recovery port 61G such that the lower surface of the porous member 64G and the second surface 22 are disposed substantially coplanarly. The recovery port 61G is connected to a liquid recovery apparatus 91G via a recovery passageway 90G. The recovery passageway 90G comprises: an internal passageway 92G of a liquid immersion member 4G; and a recovery pipe passageway 93G, which connects the internal passageway 92G and the liquid recovery apparatus 91G. By the operation of the liquid recovery apparatus 91G, the liquid LQ from the second surface 22 that contacts the lower surface of the porous member 64G flows into the internal passageway 92G via the holes of the porous member 64G and is recovered by the liquid recovery apparatus 91G.

Furthermore, in the recovery part 60G shown in FIG. 13, the porous member 64G may be omitted.

In addition, in the third embodiment as in the second embodiment, the second surface 22 may be parallel to the XY plane or may be inclined downward (i.e., in the −Z direction) toward the outer side in the radial directions with respect to the optical axis AX.

### Fourth Embodiment

A fourth embodiment will now be explained. In the explanation below, constituent parts that are identical or equivalent to those in the embodiment discussed above are assigned identical symbols, and the explanations thereof are therefore abbreviated or omitted.

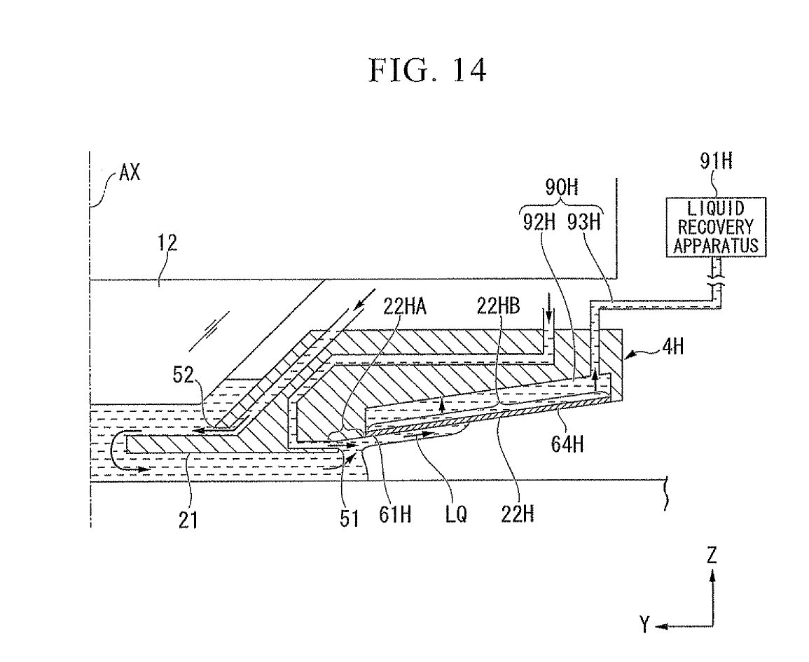

FIG. 14 is a view that shows one example of a liquid immersion member 4H according to the fourth embodiment. The first through third embodiments discussed above describe an exemplary case wherein the first surface 21 and the second surface 22 are not capable of recovering the liquid LQ. In the fourth embodiment, a second surface 22H is capable of recovering the liquid LQ.

In the present embodiment, the second surface 22H includes a lower surface of a porous member 64H. In the present embodiment, the second surface 22H includes a non-recovery surface 22HA, which is disposed on the outer side of the first supply port 51 in the radial directions with respect to the optical axis AX, and a recovery surface 22HB, which includes the lower surface of the porous member 64H. In the present embodiment, the surface area of the recovery surface 22HB is greater than that of the non-recovery surface 22HA. Namely, the recovery surface 22HB is longer than the non-recovery surface 22HA in the radial directions with respect to the optical axis AX. The liquid immersion member 4H has a recovery port 61H, which is capable of recovering the liquid LQ. The porous member 6411 is disposed in the recovery port 61H. The recovery port 61H is connected to a liquid recovery apparatus 91H via a recovery passageway 9011. The recovery passageway 9011 comprises an internal passageway 9211 of the liquid immersion member 4H and a recovery pipe passageway 9311, which connects the internal passageway 9211 and the liquid recovery apparatus 91H.

The lower surface of the porous member 64H is capable of opposing the front surface of the substrate P. The upper surface of the porous member 64H faces the internal passageway 9211.

Supplying the first liquid LQ1 from the first supply port 51 to the second surface 22H, which includes the lower surface of the porous member 64H, makes it possible to flow the liquid LQ over the second surface 22H toward the outer side in the radial directions with respect to the optical axis AX. In the present embodiment as well, it is possible to prevent the second liquid LQ2 from leaking out, remaining behind, and the like.

Furthermore, in the fourth embodiment, the suction force at the portion of the porous member 6411 that is close to the first supply port 51 and the suction force at the portion that is far from the first supply port 51 may differ (i.e., there may be a pressure differential between the upper surface and the lower surface of the porous member 64H) such that the flow of the liquid LQ (i.e., the liquid surface LQS) is formed with a prescribed length in the radial directions with respect to the optical axis AX. For example, the suction force of a porous member 64F1 may become stronger, in steps or continuously, toward the outer side in the radial directions with respect to the optical axis AX.

Furthermore, in the fourth embodiment, the second surface 22H does not have to include the non-recovery surface 22HA.

In addition, in the fourth embodiment as well, it is possible to combine the use of at least part of the configuration of the recovery part explained in each of the embodiments discussed above.

In addition, in the fourth embodiment as in the second embodiment, the second surface 22H may be parallel to the XY plane or may be inclined downward (i.e., in the −Z direction) toward the outer side in the radial directions with respect to the optical axis AX.

Furthermore, in the second through fourth embodiments discussed above as well, the supply conditions of the first liquid LQ1 supplied via the first supply port 51 may be adjusted in accordance with the movement conditions of the object (i.e., the substrate P) below the liquid immersion member.

In addition, in the first through fourth embodiments discussed above, the flow speed of the first liquid LQ1 supplied via the first supply port 51 does not have to be the same in all of the radial directions with respect to the optical axis AX. Namely, the first liquid LQ1 may be supplied at a first flow speed in a first direction among the radial directions with respect to the optical axis AX and at a second flow speed, which is different from the first flow speed, in a second direction.

### Fifth Embodiment

The following text explains a fifth embodiment. In the explanation below, constituent parts that are identical or equivalent to those in the embodiment discussed above are assigned identical symbols and the explanations thereof are therefore abbreviated or omitted.

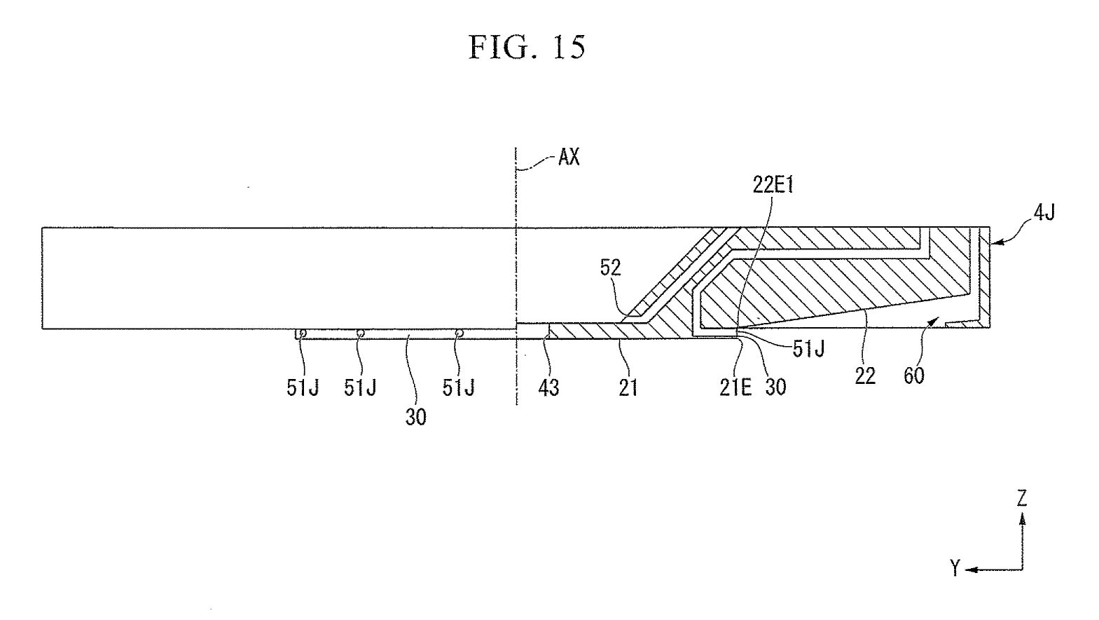

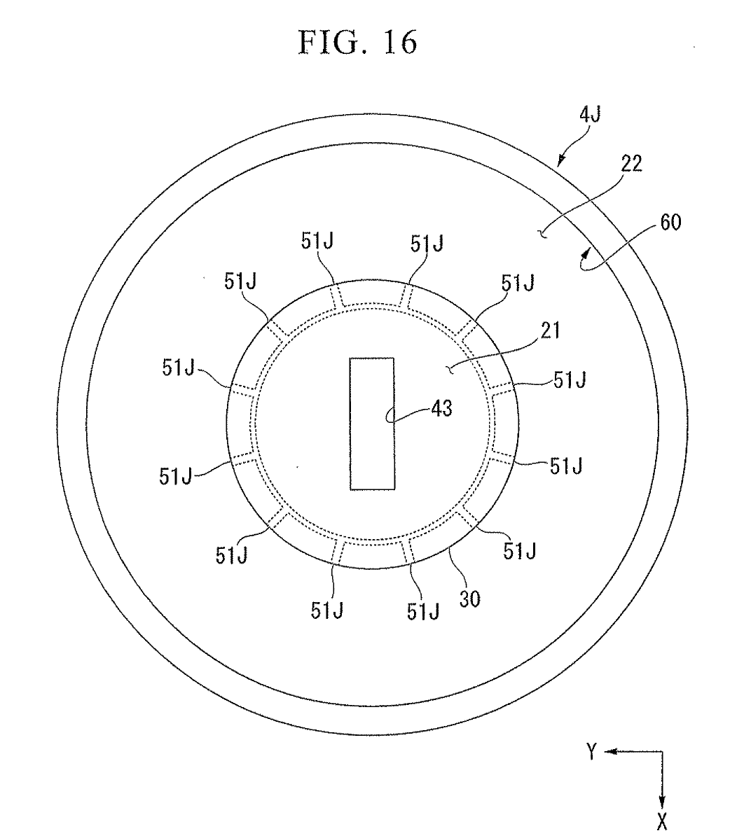

FIG. 15 is a side view that shows one example of a liquid immersion member 4J according to the fifth embodiment, wherein one part is shown in a cross sectional view. FIG. 16 shows the liquid immersion member 4J shown in FIG. 15, viewed from below.

In FIG. 15 and FIG. 16, the liquid immersion member 4J has the first surface 21, the second surface 22, and a plurality of first supply ports 51J, which supply the first liquid LQ1 to the second surface 22. In the present embodiment, the first supply ports 51J are disposed at prescribed intervals around the optical path of the exposure light EL. In the present embodiment, each of the first supply ports 51J is circular. Furthermore, the first supply ports 51J may have a shape other than circular (e.g., rectangular or slit shaped). In addition, the shapes of the first supply ports 51J may differ from one another.

In the present embodiment, the liquid immersion member 4J has a tenth surface 30, which is disposed such that it faces toward the outer side in the radial directions with respect to the optical axis AX. The tenth surface 30 is formed between the outer side edge 21E of the first surface 21 and the edge 22E1 on the inner side of the second surface 22. The angle formed between the first surface 21 and the tenth surface 30 is substantially 90°. Furthermore, the angle may be less than or greater than 90°.

The first supply ports 51J are disposed at prescribed intervals in the tenth surface 30.

In the present embodiment, each of the first supply ports 51J supplies the first liquid LQ1 at substantially the same flow speed.

In the present embodiment as well, it is possible to prevent the second liquid LQ2 from leaking out, remaining behind, and the like.

Furthermore, in the present embodiment as in each of the embodiments discussed above, the supply conditions of the first liquid LQ1 supplied via the first supply port 51J may be adjusted in accordance with the movement conditions of the object (i.e., the substrate P) below the liquid immersion member 4J. In addition, some of the first supply ports 51J of the plurality of first supply ports 51J may supply the first liquid LQ1 at the first flow speed, while the other first supply ports 51J supply the first liquid LQ1 at the second flow speed, which is different than the first flow speed. In addition, the supply of the first liquid LQ1 from some of the first supply ports 51J of the plurality of first supply ports 51J may be stopped. For example, the flow speed of the first liquid LQ1 supplied via the first supply ports 51J may differ in accordance with the movement conditions (the movement velocity, the acceleration, the linear movement distance, the movement direction, and the like) of the substrate P. For example, if the substrate P moves in the direction with respect to the optical path of the exposure light EL, then the supply of the first liquid LQ1 via the first supply ports 51J disposed on the +Y side with respect to the optical path of the exposure light EL may be stopped.

In addition, in the present embodiment, the flow of the liquid LQ (i.e., the liquid surface LQS) does not have to be formed over the second surface 22 in all of the radial directions with respect to the optical axis AX. For example, the flow of the liquid LQ (i.e., the liquid surface LQS) may be formed only on opposite sides of the exposure light EL in the Y directions with respect to the optical path of the exposure light EL.

Furthermore, in the first through fifth embodiments discussed above, the first supply ports (51, 51J) face the outer side in the radial directions with respect to the optical axis AX, but the orientation of the first supply ports (51, 51J) is not limited as long as the flow of the liquid LQ (i.e., the liquid surface LQS) is formed over the second surface 22 in the radial directions with respect to the optical axis AX.

In addition, in the first through fifth embodiments discussed above, the liquid surface LQS is formed by the flow of the liquid LQ over the second surface 22 (22B, 22C, 22H); however, in at least part of the second surface 22 (22B, 22C, 22H), a gas space may exist between the second surface 22 (22B, 22C, 22H) and the liquid LQ. Namely, the flow of the liquid LQ (i.e., the liquid surface LQS) toward the outer side in the radial directions with respect to the optical axis AX should be formed on the outer side of the immersion space LS in the radial directions with respect to the optical axis AX.

Furthermore, in the first through fifth embodiments discussed above, the first surface 21 is disposed partly around the optical path of the exposure light EL. In addition, the second surface 22 (22B, 22C, 22H) may be disposed partly around the first surface 21.

Furthermore, in each of the embodiments discussed above, at least part of the second surface 22 (22B, 22C, 22H) may be disposed below the first surface 21. For example, if the second surface 22C is inclined downward toward the outer side in the radial directions, as with the liquid immersion member 4C shown in FIG. 9, then an edge (i.e., a circumferential edge area) on the outer side of the second surface 22C may be disposed below the first surface 21.

Furthermore, in each of the embodiments discussed above, the first surface 21 and the second surface 22 (22B, 22C, 22H) are substantially flat, but at least part of the second surface 22 (22B, 22C, 22H) may include a curved surface. In addition, at least part of the first surface 21 may include a curved surface. In addition, the first surface 21 may be inclined with respect to the XY plane. In addition, a groove that is long in the radial directions may be formed in the second surface 22 (22B, 22C, 22H). In addition, the third surface 23 and the first surface 21 do not have to be parallel.

Furthermore, in each of the embodiments discussed above, the second supply ports 52 supply the second liquid LQ2 to the space between the emergent surface 11 and the third surface 23 of the plate part 41, but they may supply the second liquid LQ2 to the space between the side surface 12F and the inner side surface 44. In addition, the second supply ports 52 may be disposed such that they oppose the side surface 12F of the last optical element 12. Furthermore, in addition to or instead of the second supply ports 52, a supply port that supplies the second liquid LQ2 may be provided to the first surface 21.

Furthermore, in each of the embodiments discussed above, the plate part 41 may be omitted. For example, the first surface 21 may be provided at least partly around the emergent surface 11. In this case, the first surface 21 may be disposed at the same height as or above (i.e., on the +Z side of) the emergent surface 11.

Furthermore, in each of the embodiments discussed above, the liquid immersion member 4 may be capable of moving with respect to the projection optical system PL (i.e., the last optical element 12).

In addition, each of the embodiments discussed above explained a case wherein the first surface 21, the second surface 22, and the first supply port 51 are disposed in the same liquid immersion member 4, but the first surface 21 and the second surface 22 may be disposed in separate members, the first surface 21 and the first supply port 51 may be disposed in separate members, and the second surface 22 and the first supply port 51 may be disposed in separate members. In addition, the member wherein the second surface 22 is disposed and the member wherein the recovery part 60 is disposed may be different members. In such a case, at least some of the members of the plurality of members may be moveable with respect to the projection optical system PL (i.e., the last optical element 12).

Furthermore, in each of the embodiments discussed above, the immersion space LS is formed with the second liquid LQ2, but it may be formed with the first liquid LQ1 and the second liquid LQ2 by mixing some of the first liquid LQ1 in the second liquid LQ2. In each of the embodiments discussed above, the first liquid LQ1 and the second liquid LQ2 are the same liquid and therefore it does not matter whether the first liquid LQ1 is present in the optical path of the exposure light EL.

Furthermore, each of the embodiments discussed above explained exemplary cases wherein the first liquid LQ1 and the second liquid LQ2 are the same liquid, but they may be different liquids. For example, a liquid that has prescribed physical properties suited to the exposure of the substrate P may be used as the second liquid LQ2, and a liquid that is more lyophilic than the second liquid LQ2 with respect to the second surface 22 may be used as the first liquid LQ1.

In addition, the quality (i.e., the cleanliness level, the degree of transparency, and the like) of the first liquid LQ1 may be lower than that of the second liquid LQ2. In such a case, it would be preferable to dispose the first supply port 51 and set the supply conditions of the first liquid LQ1 supplied via the first supply port 51 such that the first liquid LQ1 supplied via the first supply port 51 does not mix with the second liquid LQ2 over the optical path of the exposure light EL.

Furthermore, in each of the embodiments discussed above, an adjustment is made such that the temperature of the first liquid LQ1 supplied via the first supply port 51 and the temperature of the second liquid LQ2 supplied via the second supply ports 52 are substantially the same, but the temperature of the first liquid LQ1 supplied via the first supply port 51 and the temperature of the second liquid LQ2 supplied via the second supply ports 52 may be different. In addition, the temperature of the liquid immersion member 4 may be adjusted using the first liquid LQ1 that flows through the internal passageway 72.

Furthermore, in each of the embodiments discussed above, a gas supply port that supplies gas to the vicinity of the air-liquid interface LG of the second liquid LQ2 of the immersion space LS may be provided. For example, the gas may be supplied to the vicinity of the air-liquid interface LG via the gas supply port such that a gas seal is formed between the front surface of the substrate P and the second surface 22. The force of the gas supplied via the gas supply port prevents the immersion space LS from enlarging. Thereby, the force of the gas supplied via the gas supply port also prevents the second liquid LQ2 from leaking out, remaining behind, and the like.

Furthermore, in each of the embodiments discussed above, the optical path on the emergent (image plane) side of the last optical element 12 of the projection optical system PL is filled with the second liquid LQ2; however, it is possible to use a projection optical system wherein the optical path on the incident (object plane) side of the last optical element 12 is also filled with a liquid, as disclosed in, for example, PCT International Publication No. WO2004/019128, Furthermore, the liquid that fills the optical path on the incident side of the last optical element 12 may be the same type of liquid as the second liquid LQ2 or may be of a different type.

Furthermore, in each of the embodiments discussed above, the first and second liquids LQ1, LQ2 are not limited to water (i.e., pure water); for example, it is also possible to use hydro-fluoro-ether (HFE), perfluorinated polyether (PFPE), Fomblin® oil, and the like.

Furthermore, the substrate P in each of the embodiments discussed above is not limited to a semiconductor wafer for fabricating semiconductor devices, but can also be adapted to, for example, a glass substrate for display devices, a ceramic wafer for thin film magnetic heads, or the original plate of a mask or a reticle (i.e., synthetic quartz or a silicon wafer) used by an exposure apparatus.

The exposure apparatus EX can also be adapted to a step-and-scan type scanning exposure apparatus (i.e., a scanning stepper) that scans and exposes the pattern of the mask M by synchronously moving the mask M and the substrate P as well as to a step-and-repeat type projection exposure apparatus (i.e., a stepper) that successively steps the substrate P and performs a full-field exposure of the pattern of the mask M with the mask M and the substrate P in a stationary state.

Furthermore, when performing an exposure with a step-and-repeat system, the projection optical system PL is used to transfer a reduced image of a first pattern to the substrate P in a state wherein the first pattern and the substrate P are substantially stationary, after which the projection optical system PL may be used to perform a full-field exposure of the substrate P, wherein a reduced image of a second pattern partially superposes the transferred first pattern in a state wherein the second pattern and the substrate P are substantially stationary (i.e., as in a stitching type full-field exposure apparatus). In addition, the stitching type exposure apparatus can also be adapted to a step-and-stitch type exposure apparatus that successively steps the substrate P and transfers at least two patterns onto the substrate P such that they are partially superposed.

In addition, the exposure apparatus EX can be, for example, an exposure apparatus that combines the patterns of two masks onto a substrate through a projection optical system and double exposes, substantially simultaneously, a single shot region on the substrate using a single scanning exposure, as disclosed in, for example, U.S. Pat. No. 6,611,316. In addition, the exposure apparatus EX can be, for example, a proximity type exposure apparatus and a mirror projection aligner.

In addition, the exposure apparatus EX can be a twin stage type exposure apparatus, which comprises a plurality of substrate stages, as disclosed in, for example, U.S. Pat. Nos. 6,341,007, 6,208,407, and 6,262,796. In this case, the liquid immersion space LS can be formed over each of the substrate stages or such that it spans the plurality of substrate stages.

Furthermore, as disclosed in, for example, U.S. Pat. No. 6,897,963 and U.S. Patent Application Publication No. 2007/0127006, the exposure apparatus EX can be an exposure apparatus that is provided with: a substrate stage, which holds the substrate; and a measurement stage that does not hold the substrate to be exposed and whereon a fiducial member, wherein a fiducial mark is formed, various photoelectric sensors, or the like are mounted. In addition, the exposure apparatus EX can be an exposure apparatus that comprises a plurality of substrate stages and measurement stages. In this case, the liquid immersion space LS can be formed over the measurement stages or such that it spans the plurality of substrate stages and the measurement stages.

The type of exposure apparatus EX is not limited to a semiconductor device fabrication exposure apparatus that exposes the substrate P with the pattern of a semiconductor device, but can also be widely adapted to exposure apparatuses used to fabricate, for example, liquid crystal display devices or displays, and to exposure apparatuses used to fabricate thin film magnetic heads, image capturing devices (CCDs), micromaehines, MEMS devices, DNA chips, or reticles and masks.

In addition, in each of the embodiments discussed above, an ArF excimer laser may be used as a light source apparatus that generates ArF excimer laser light, which serves as the exposure light EL; however, as disclosed in, for example, U.S. Pat. No. 7,023,610, a harmonic generation apparatus may be used that outputs pulsed light with a wavelength of 193 nm and that comprises: an optical amplifier part, which has a solid state laser light source (such as a DFB semiconductor laser or a fiber laser), a fiber amplifier, and the like; and a wavelength converting part. Moreover, in the abovementioned embodiments, both the illumination region IR and the projection region PR discussed above are rectangular, but they may be some other shape, for example, arcuate.

Furthermore, in each of the embodiments discussed above, an optically transmissive mask is used wherein a prescribed shielding pattern (or phase pattern or dimming pattern) is formed on an optically transmissive substrate; however, instead of such a mask, a variable shaped mask (also called an electronic mask, an active mask, or an image generator), wherein a transmissive pattern, a reflective pattern, or a light emitting pattern is formed based on electronic data of the pattern to be exposed, may be used as disclosed in, for example, U.S. Pat. No. 6,778,257. The variable shaped mask comprises a digital micromirror device (DMD), which is one kind of non-emissive type image display device (e.g., a spatial light modulator). In addition, instead of a variable shaped mask that comprises a non-emissive type image display device, a pattern forming apparatus that comprises a self luminous type image display device may be provided. Examples of a self luminous type image display device include a cathode ray tube (CRT), an inorganic electroluminescence display, an organic electroluminescence display (OLED: organic light emitting diode), an LED display, a laser diode (LD) display, a field emission display (FED), and a plasma display panel (PDP).

Each of the embodiments discussed above explained an exemplary case of an exposure apparatus that comprises the projection optical system PL, but an embodiment can comprise an exposure apparatus and an exposing method that do not use the projection optical system PL. Thus, even if the projection optical system PL is not used, the exposure light EX can be radiated to the substrate P through optical members, such as lenses, and an immersion space LS can be formed in a prescribed space between the substrate P and those optical members.

In addition, by forming interference fringes on the substrate P as disclosed in, for example, PCT International Publication No. WO2001/035168, the present invention can also be adapted to an exposure apparatus (i.e., a lithographic system) that exposes the substrate P with a line-and-space pattern.

As described above, the exposure apparatus EX of the present embodiment is manufactured by assembling various subsystems as well as each constituent element recited in the claims of the present application, such that prescribed mechanical, electrical, and optical accuracies are maintained. To ensure these various accuracies, adjustments are performed before and after this assembly, including an adjustment to achieve optical accuracy for the various optical systems, an adjustment to achieve mechanical accuracy for the various mechanical systems, and an adjustment to achieve electrical accuracy for the various electrical systems. The process of assembling the exposure apparatus EX from the various subsystems includes, for example, the mechanical interconnection of the various subsystems, the wiring and connection of electrical circuits, and the piping and connection of the atmospheric pressure circuit. Naturally, prior to performing the process of assembling the exposure apparatus EX from these various subsystems, there are also the processes of assembling each individual subsystem. When the process of assembling the exposure apparatus EX from the various subsystems is complete, a comprehensive adjustment is performed to ensure the various accuracies of the exposure apparatus EX as a whole. Furthermore, it is preferable to manufacture the exposure apparatus EX in a clean room, wherein the temperature, the cleanliness level, and the like are controlled.

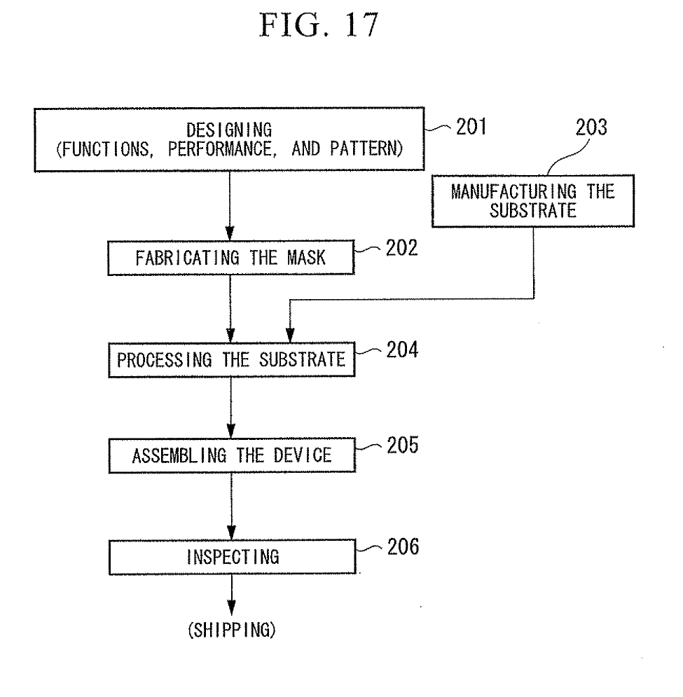

As shown in FIG. 17, a micro-device, such as a semiconductor device, is manufactured by: a step 201 that designs the functions and performance of the micro-device; a step 202 that fabricates the mask M (i.e., a reticle) based on this designing step; a step 203 that manufactures the substrate P, which is the base material of the device; a substrate processing step 204 that includes, in accordance with the embodiments discussed above, exposing the substrate P with the exposure light EX using the pattern of the mask M and developing the exposed substrate P; a device assembling step 205 (which includes fabrication processes such as dicing, bonding, and packaging processes); an inspecting step 206; and the like.

Furthermore, the features of each of the embodiments discussed above can be combined as appropriate. In addition, there may be cases wherein some of the constituent elements are not used. In addition, each disclosure of every published document and U.S. patent related to the exposure apparatus recited in each of the embodiments, modified examples, and the like discussed above is hereby incorporated by reference in its entirety to the extent permitted by national laws and regulations.

1. An exposure apparatus, comprising:
an optical system, which has an emergent surface wherefrom exposure light emerges;
a first surface, which is disposed at least partly around an optical path of the exposure light from the emergent surface; and
a second surface, which is disposed at least partly around the first surface; and
a first supply port, which is disposed at least partly around the first surface such that the first supply port faces in an outward radial direction with respect to an optical axis of the optical system, and which supplies a first liquid to the second surface;
wherein,
during at least part of an exposure of a substrate, a front surface of the substrate opposes the emergent surface, the first surface, and the second surface; and
the substrate is exposed with the exposure light that emerges from the emergent surface and transits a second liquid between the emergent surface and the front surface of the substrate.

2. The exposure apparatus according to claim 1, wherein
the first supply port supplies the first liquid such that the first liquid flows over the second surface in an outward radial direction.

3. The exposure apparatus according to claim 1, wherein
in the state wherein the second liquid is held between the emergent surface and an object, the first supply port supplies the first liquid in accordance with a movement condition when the object moves in a first direction within a prescribed plane that is substantially parallel to the emergent surface.

4. The exposure apparatus according to claim 3, further comprising:
an adjusting apparatus that adjusts a supply condition of the first liquid supplied via the first supply port in accordance with the movement condition of the object.

5. The exposure apparatus according to claim 3, wherein
the movement condition includes a movement velocity of the object in the first direction; and
the supply condition includes a flow speed of the first liquid supplied via the first supply port substantially parallel to the first direction.

6. The exposure apparatus according to claim 5, wherein
the flow speed of the first liquid supplied via the first supply port is greater than or equal to the movement velocity of the object.

7. The exposure apparatus according to claim 1, wherein
at least part of the second surface is disposed above the first surface.

8. The exposure apparatus according to claim 1, wherein
at least part of the second surface is inclined upward in an outward radial direction.

9. The exposure apparatus according to claim 1, wherein
the first surface and the second surface are substantially parallel.

10. The exposure apparatus according to claim 1, wherein
the second surface is lyophilic with respect to the first liquid.

11. The exposure apparatus according to claim 1, further comprising:
a second supply port that supplies the second liquid to the optical path.

12. The exposure apparatus according to claim 11, further comprising:
a third surface that is disposed around the optical path such that it faces a direction that is opposite that of the first surface and at least part of it opposes the emergent surface;
herein
the second supply port supplies the second liquid to the space between the emergent surface and the third surface.

13. The exposure apparatus according to claim 11, wherein
the supply of the first liquid via the first supply port and the supply of the second liquid via the second supply port is performed in parallel.

14. The exposure apparatus according to claim 11, wherein
an immersion space is formed between at least part of the emergent surface, the first surface, and the second surface and the front surface of the object by at least some of the second liquid supplied via the second supply port such that the optical path of the exposure light between the emergent surface and the object is filled with the second liquid; and
the first supply port, in the state wherein it is disposed in the immersion space, supplies the first liquid.

15. The exposure apparatus according to claim 1, wherein
the first liquid and the second liquid are the same type of liquid.

16. The exposure apparatus according to claim 1, wherein
the first supply port includes a slit opening, which is formed such that it surrounds the optical path.

17. The exposure apparatus according to claim 1, wherein
a plurality of the first supply ports is disposed at prescribed intervals around the optical path.

18. The exposure apparatus according to claim 1, further comprising:
a recovery part, which is disposed on the outer side of the second surface in the radial direction with respect to the optical axis and recovers at least some of the liquid on the second surface.

19. The exposure apparatus according to claim 18, wherein
the recovery part comprises a recovery port, which is capable of recovering at least some of the liquid on the second surface, and a porous member, which is disposed in the recovery port.

20. The exposure apparatus according to claim 18, wherein
the recovery part has a fourth surface, which is disposed such that it intersects the second surface.

21. The exposure apparatus according to claim 20, wherein
a first gap is formed between an edge on the outer side of the second surface and the fourth surface; and
the recovery part recovers at least some of the liquid that flows in from the second surface to the first gap.

22. The exposure apparatus according to claim 20, wherein
at least part of the fourth surface is disposed below an edge on the outer side of the second surface such that it faces the optical axis.

23. The exposure apparatus according to claim 18, wherein
the recovery part has a recessed part, which is disposed such that it faces upward below the circumferential edge area of the second surface.

24. The exposure apparatus according to claim 23, wherein
the recovery part recovers at least some of the liquid that flows into the recessed part.

25. A device fabricating method, comprising:
exposing a substrate using an exposure apparatus according to claim 1; and
developing the exposed substrate.

26. An exposing method, comprising:
causing a first surface, which is disposed at least partly around an optical path of exposure light that emerges from an emergent surface of an optical system, and a second surface, which is disposed at least partly around the first surface, to a substrate;
at least partly around the first surface, supplying a first liquid via a first supply port, which is disposed such that it faces in an outward radial direction with respect to the optical axis of the optical system, to the second surface;
forming an immersion space with a second liquid between at least part of the emergent surface, the first surface, and the second surface and a front surface of the substrate by supplying the second liquid via a second supply port, which is different than the first supply port, such that the optical path of the exposure light between the emergent surface and the substrate is filled with the second liquid; and
exposing the substrate with the exposure light that emerges from the emergent surface and transits the second liquid between the emergent surface and the substrate.

27. An exposing method, comprising:
causing a first surface, which is disposed at least partly around an optical path of exposure light that emerges from an emergent surface of an optical system, and a second surface, which is disposed at least partly around the first surface, to oppose a substrate;
at least partly around the first surface, forming a flow of a liquid in an outward radial direction with respect to the optical axis of the optical system by supplying a first liquid to the second surface;
forming an immersion space with a second liquid between at least part of the emergent surface, the first surface, and the second surface and a front surface of the substrate such that the optical path of the exposure light between the emergent surface and the substrate is filled with the second liquid; and
exposing the substrate with the exposure light that emerges from the emergent surface and transits the second liquid between the emergent surface and the substrate;
wherein,
a gas space is present between a surface of the liquid, which flows in an outward radial direction with respect to the optical axis of the optical system, and the front surface of the substrate.

28. The exposing method according to claim 27, wherein
the liquid that flows toward in the outward radial direction with respect to the optical axis of the optical system comprises the first liquid and the second liquid.

29. The exposing method according to claim 26, wherein
the first liquid and the second liquid are the same type of liquid.

30. A device fabricating method, comprising:
exposing a substrate using an exposing method according to claim 26; and
developing the exposed substrate.

31. A liquid immersion member that is disposed in an exposure apparatus that exposes a substrate with an exposure light from an emergent surface of an optical system, the liquid immersion member comprising:
a first surface, which is disposed at least partly around an optical path of the exposure light from the emergent surface; and
a second surface, which is disposed at least partly around the first surface;
a first supply port, which is disposed at least partly around the first surface such that the first supply port faces in an outward radial direction with respect to an optical axis of the optical system, and which supplies a first liquid to the second surface; and
a second supply port that supplies a second liquid to an optical path of the exposure light.
